(19) United States
(12) Patent Application Publication
(10) Pub. No.: US 2017/0221899 A1
(43) Pub. Date: Aug. 3, 2017

(54) Microcontroller System

(71) Applicant: Semiconductor Energy Laboratory Co., Ltd., Kanagawa-ken (JP)

(72) Inventors: Wataru UESUGI, Yashio (JP); Hikaru TAMURA, Hadano (JP)

(73) Assignee: Semiconductor Energy Laboratory Co., Ltd., Kanagawa-ken (JP)

(21) Appl. No.: 15/416,262

(22) Filed: Jan. 26, 2017

(30) Foreign Application Priority Data
Jan. 29, 2016 (JP) 2016-015353

(51) Int. Cl. H01L 27/105; H01L 29/786; H01L 27/12

(52) U.S. Cl. CPC H01L 27/1052; H01L 27/1225; H01L 27/1255; H01L 27/124; H01L 29/7869

(57) ABSTRACT

An object is to provide a microcontroller (MCU) system with low power consumption. The MCU system includes a CPU, a first memory cell, and a second memory cell. The first memory cell includes a first transistor and a first capacitor. The second memory cell includes a second transistor and a second capacitor. The first memory cell functions as a data memory. The second memory cell functions as a program memory. Each of the first and second transistors contains an oxide semiconductor in a channel formation region. The capacitance of the second capacitor is preferably larger than that of the first capacitor.

### BACKGROUND OF THE INVENTION

1. Field of the Invention

One embodiment of the present invention relates to a semiconductor device or a microcontroller system.

One embodiment of the present invention relates to an object, a method, and a manufacturing method. In addition, one embodiment of the present invention relates to a process, a machine, manufacture, and a composition of matter. One embodiment of the present invention relates to a method for driving a semiconductor device or a method for manufacturing a semiconductor device.

In this specification and the like, a semiconductor device generally means a device that can function by utilizing semiconductor characteristics. In some cases, a memory device, a display device, an electro-optical device, a semiconductor circuit, or an electronic device includes a semiconductor device.

2. Description of the Related Art

Memories in a microcontroller (hereinafter referred to as MCU) are classified into a program memory for storing a program and a data memory for storing data handled by a central processing unit (CPU). Flash memory is used for the program memory and static random access memory (SRAM) is used for the data memory in many cases.

A transistor containing an oxide semiconductor (OS) in a channel formation region (hereinafter such a transistor is referred to as OS transistor) is known. A variety of semiconductor devices including OS transistors have been proposed.

Patent Document 1 discloses an example in which an OS transistor is used in dynamic random access memory (DRAM). The OS transistor has an extremely low leakage current in an off state (off-state current), and thus enables a memory to have low power consumption and long intervals between refresh operations.

### PATENT DOCUMENT

Patent Document 1: Japanese Published Patent Application No. 2013-168631

### SUMMARY OF THE INVENTION

Flash memory has an advantage of nonvolatility but has a disadvantage of high power consumption in data writing. SRAM has an advantage of high operating speed for data writing and reading, but has a disadvantage of high power consumption because leakage current flows constantly. Thus, an MCU including flash memory and SRAM has high power consumption.

When the above MCU is used in an electronic device in which power is supplied from a battery (e.g., a mobile appliance), the MCU consumes power of the battery and thus, the operable time of the electronic device is shortened.

An object of one embodiment of the present invention is to provide an MCU with low power consumption. Another object of one embodiment of the present invention is to provide an MCU system with low power consumption. Another object of one embodiment of the present invention is to provide a semiconductor device with low power consumption. Another object of one embodiment of the present invention is to provide a novel semiconductor device.

Note that the description of a plurality of objects does not preclude the existence of each object. One embodiment of the present invention does not necessarily achieve all the objects listed above. Objects other than those listed above are apparent from the description of the specification, drawings, claims, and the like, and such objects could be an object of one embodiment of the present invention.

One embodiment of the present invention is a semiconductor device including a CPU, a first memory cell, and a second memory cell. The first memory cell includes a first transistor and a first capacitor. The second memory cell includes a second transistor and a second capacitor. The first memory cell serves as a data memory. The second memory cell serves as a program memory. The first transistor contains an oxide semiconductor in a channel formation region. The second transistor contains an oxide semiconductor in a channel formation region. The capacitance of the second capacitor is preferably larger than that of the first capacitor.

In the above embodiment, the first capacitor has a trench, and the second capacitor has a trench. The capacitance of the second capacitor is preferably i times that of the first capacitor (i is an integer of 2 or more).

In any of the above embodiments, the capacitance of the first capacitor is preferably 5 fi or less.

One embodiment of the present invention is a microcontroller system including the semiconductor device of any of the above embodiments.

One embodiment of the present invention is an electronic device including the semiconductor device of any of the above embodiments, and a battery.

One embodiment of the present invention is an electronic device including the semiconductor device of any of the above embodiments, a sensor, an antenna, and a battery.

One embodiment of the present invention is a semiconductor wafer including a plurality of semiconductor devices of any of the above embodiments, and a separation region.

One embodiment of the present invention can provide an MCU with low power consumption, an MCU system with low power consumption, a semiconductor device with low power consumption, or a novel semiconductor device.

Note that the description of these effects does not preclude the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

In the accompanying drawings:

FIGS. 1A to 1D are a block diagram illustrating a structure example of an MCU and circuit diagrams each illustrating a configuration example of a memory cell;

FIGS. 2A to 2D are top views and cross-sectional views for explaining a trench;

FIG. 3 is a block diagram illustrating a structure example of a CPU;

FIG. 4 is a circuit block diagram illustrating a structure example of a data memory 12;

FIG. 5 is a circuit diagram illustrating a configuration example of a sense amplifier;

FIG. 6 is a timing chart illustrating an operation example of a sense amplifier;

FIG. 7 is a circuit diagram illustrating a structure example of a circuit 100;

FIG. 8 is a circuit diagram illustrating a configuration example of a voltage retention circuit 101;

FIGS. 9A and 9B are circuit diagrams each illustrating a configuration example of a voltage generator circuit 102;

FIGS. 10A to 10F are perspective views of electronic devices;

FIGS. 11A and 11B are perspective views illustrating a structure example of a wireless sensor;

FIG. 12 is a perspective view illustrating a structure example of a wireless sensor;

FIG. 13 is a schematic view illustrating an application example of a wireless sensor;

FIGS. 14A and 14B are schematic views each illustrating an application example of a wireless sensor;

FIG. 15 is a schematic view illustrating an application example of a wireless sensor;

FIG. 16 is a cross-sectional view illustrating a structure example of an MCU;

FIG. 17 is a cross-sectional view illustrating a structure example of an MCU;

FIGS. 18A and 18B are cross-sectional views each illustrating a structure example of a transistor M1;

FIGS. 19A to 19C illustrate a crystal of InMZnO₄;

FIGS. 20A to 20C are a top view and cross-sectional views illustrating a structure example of a transistor;

FIGS. 21A to 21C are a top view and cross-sectional views illustrating a structure example of a transistor;

FIGS. 22A to 22C are a top view and cross-sectional views illustrating a structure example of a transistor;

FIGS. 23A to 23C are a top view and cross-sectional views illustrating a structure example of a transistor;

FIGS. 24A to 24C are a top view and cross-sectional views illustrating a structure example of a transistor;

FIGS. 25A to 25C are a top view and cross-sectional views illustrating a structure example of a transistor;

FIGS. 26A and 26B are top views of a semiconductor wafer;

FIGS. 27A and 27B are a flow chart illustrating steps of manufacturing a semiconductor device and a perspective view of the semiconductor device; and

FIG. 28 is a graph of V_{FN} over time, obtained by SPICE simulation.

### DETAILED DESCRIPTION OF THE INVENTION

Embodiments of the present invention will be described in detail with reference to the accompanying drawings. Note that the present invention is not limited to the following description, and it will be readily appreciated by those skilled in the art that modes and details of the present invention can be modified in various ways without departing from the spirit and scope of the present invention. Therefore, the present invention should not be limited to the descriptions of the embodiments and example below.

Note that in structures of the present invention described below, the same portions or portions having similar functions are denoted by the same reference numerals in different drawings, and description thereof is not repeated. Furthermore, the same hatching pattern is used for portions having similar functions, and the portions are not especially denoted by reference numerals in some cases.

Note that in each drawing described in this specification, the size, the layer thickness, or the region of each component is sometimes exaggerated for clarity. Therefore, the size, the layer thickness, or the region is not limited to the illustrated scale.

Unless otherwise specified, an on-state current in this specification refers to a drain current of a transistor in an on state. Unless otherwise specified, the on state of an n-channel transistor means that the voltage (V_{G}) between its gate and source is higher than or equal to the threshold voltage (Vₜₕ), and the on state of a p-channel transistor means that V_{G} is lower than or equal to Vₜₕ. For example, the on-state current of an n-channel transistor sometimes refers to a drain current that flows when V_{G} is higher than or equal to Vₜₕ. The on-state current of a transistor sometimes depends on a voltage (V_{D}) between a drain and a source.

Unless otherwise specified, an off-state current in this specification refers to a drain current of a transistor in an off state. Unless otherwise specified, the off state of an n-channel transistor means that V_{G} is lower than Vₜₕ, and the off state of a p-channel transistor means that V_{G} is higher than Vₜₕ. For example, the off-state current of an n-channel transistor sometimes refers to a drain current that flows when V_{G} is lower than Vₜₕ. The off-state current of a transistor depends on V_{G} in some cases. Thus, “the off-state current of a transistor is lower than 10⁻²¹ A” may mean there is V_{G} at which the off-state current of the transistor is lower than 10⁻²¹ A.

The off-state current of a transistor depends on V_{D} in some cases. Unless otherwise specified, the off-state current in this specification may be an off-state current at V_{D} with an absolute value of 0.1 V, 0.8 V, 1 V, 1.2 V, 1.8 V, 2.5 V, 3 V, 3.3 V, 10 V, 12 V, 16 V, or 20 V. Alternatively, the off-state current may be an off-state current at V_{D} used in a semiconductor device or the like including the transistor.

In this specification and the like, the terms “one of a source and a drain” (or a first electrode or a first terminal) and “the other of the source and the drain” (or a second electrode or a second terminal) are used to describe the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In this specification, a high power supply potential is referred to as H level (or V_{DD}) and a low power supply potential is referred to as L level (or GND) in some cases.

In this specification, any of the embodiments and the example below can be combined as appropriate. In addition, in the case where a plurality of structure examples are described in one embodiment, some of the structure examples can be combined as appropriate.

### Embodiment 1

In this embodiment, an MCU system of one embodiment of the present invention will be described.

### <MCU 10>

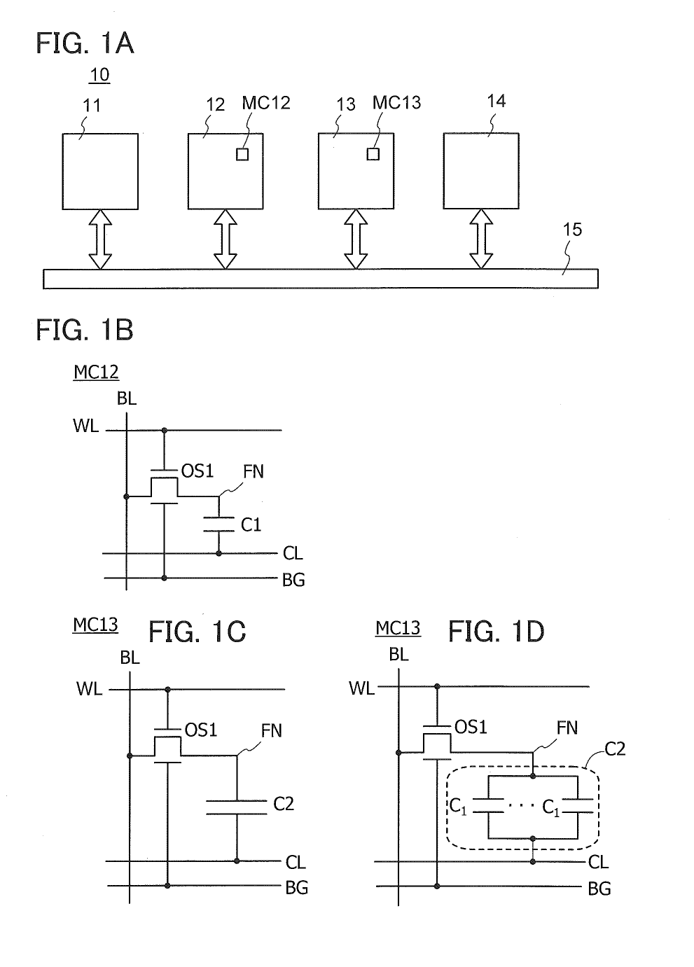

FIG. 1A is a block diagram illustrating a structure example of an MCU system. An MCU 10 illustrated in FIG. 1A includes a CPU 11, a data memory 12, a program memory 13, a peripheral circuit 14, and a bus 15. Data is exchanged between the CPU 11, the data memory 12, the program memory 13, and the peripheral circuit 14 through the bus 15. Note that the CPU 11 may be referred to as a CPU core.

The data memory 12 has a function of temporarily storing data handled by the CPU 11. The data memory 12 includes a memory cell MC12.

The program memory 13 has a function of storing a program. The MCU 10 operates in accordance with a program stored in the program memory 13. The program memory 13 includes a memory cell MC13.

The data memory 12 preferably performs data reading and writing at high speed because it is frequently accessed from the CPU 11. Meanwhile, the program memory 13 is preferably capable of retaining data for a long time.

FIG. 1B illustrates an example of a circuit configuration of the memory cell MC12. The memory cell MC12 includes a transistor OS1, a capacitor C1, a wiring BL, a wiring WL, a wiring CL, and a wiring BG.

The transistor OS1 includes a first gate and a second gate. There is preferably a region where the first gate and the second gate of the transistor OS1 overlap each other with a semiconductor layer therebetween.

The first gate of the transistor OS1 is electrically connected to the wiring WL. A first terminal of the transistor OS1 is electrically connected to a first terminal of the capacitor C1. A second terminal of the transistor OS1 is electrically connected to the wiring BL. A second terminal of the capacitor C1 is electrically connected to the wiring CL. The second gate of the transistor OS1 is electrically connected to the wiring BG. Here, a node of the first terminal of the transistor OS1 and the first terminal of the capacitor C1 is denoted by a node FN.

The wiring BL functions as a bit line. Data (potential) supplied to the wiring BL is written to the node FN through the transistor OS1.

The wiring WL functions as a word line. When an H-level potential is supplied to the wiring WL, the transistor OS1 is turned on, and the potential of the wiring BL is written to the node FN. A potential supplied to the wiring WL is preferably higher than the sum of a potential supplied to the wiring BL and Vₜₕ of the transistor OS1.

The wiring CL is supplied with a constant potential (e.g., GND).

The wiring BG has a function of supplying a potential to the second gate of the transistor OS1. For example, when a negative potential is supplied to the wiring BG, Vₜₕ of the transistor OS1 can be increased (Vₜₕ can be shifted in the positive direction). As a result, the amount of cutoff current (drain current at V_{G}=0 V) of the transistor OS1 can be decreased. Moreover, the transistor OS1 can be prevented from having normally-on characteristics.

The transistor OS1 is preferably a transistor with a low off-state current. As the transistor with a low off-state current, an OS transistor or a transistor containing a wide-bandgap semiconductor in a channel formation region is preferably used. Note that in this specification, a wide-bandgap semiconductor is a semiconductor whose bandgap is 2.2 eV or greater. Examples of the wide-bandgap semiconductor include silicon carbide, gallium nitride, and diamond.

The low off-state current of the transistor OS1 enables a reduction in leakage of charge held at the node FN. Thus, data stored in the memory cell MC12 can be retained for a long time, and the interval between refresh operations can be long.

The memory cell MC12 included in the data memory preferably operates at high speed. For that reason, the capacitance (C₁) of the capacitor C1 is preferably small. For example, when the MCU 10 operates at 200 MHz, the MCU 10 needs to operate in 5 nanoseconds (ns) for each clock. Accordingly, the capacitor C1 in the memory cell MC12 is preferably charged in approximately 2 ns. To perform the above writing operation, C₁ needs to be 8 fF or less, preferably 6 fF or less, further preferably 5 fF or less.

FIG. 1C illustrates a circuit configuration of the memory cell MC13. In the memory cell MC13, the capacitor C1 in the memory cell MC12 is replaced with a capacitor C2.

The memory cell MC13 included in the program memory preferably has a longer data retention time than the memory cell MC12. For that reason, the capacitance (C₂) of the capacitor C2 is preferably larger than C₁. A larger C₂ leads to lower writing speed of the memory cell MC13; however, it will not cause any problem because the memory cell MC13 is not accessed frequently. Note that C₂ is preferably two times or more, further preferably three times or more, still further preferably four times or more, still further preferably five times or more C₁.

When each of the capacitors C1 and C2 has a trench, C₂ is preferably i times C₁ (i is an integer of 2 or more). FIG. 1D is a circuit diagram of the memory cell MC13 in that case. As the capacitor C2 illustrated in FIG. 1D, capacitors each having C₁ are connected in parallel. Note that in this specification, the expression “C₂ is i times C₁” means that C₂ ranges from C₁×i×0.9 to C₁×i×1.1.

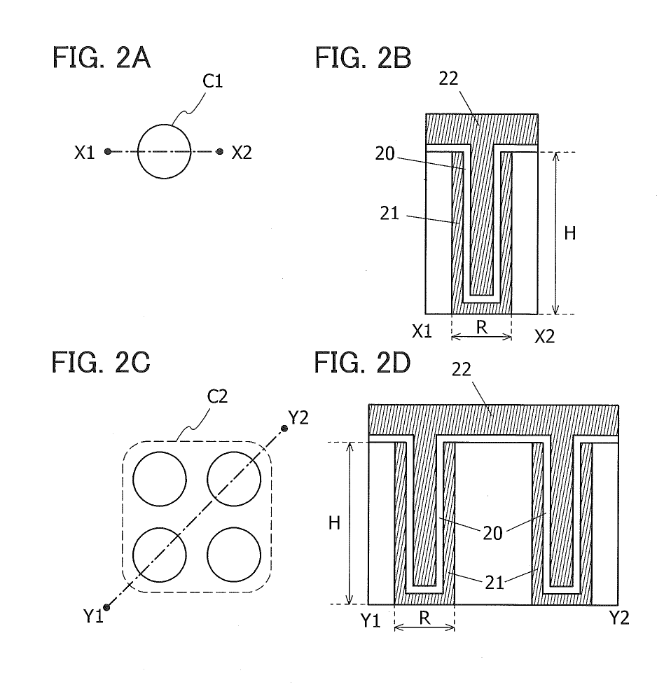

Here, the capacitor with a trench will be described with reference to FIGS. 2A to 2D. FIG. 2A is a top view of the capacitor C1 having a trench. FIG. 2B is a cross-sectional view along the dashed-dotted line X1-X2 in the top view of FIG. 2A. Similarly, FIG. 2C is a top view of the capacitor C2 having trenches, and FIG. 2D is a cross-sectional view along the dashed-dotted line Y1-Y2 in the top view of FIG. 2C. Each of the capacitors C1 and C2 is formed of an insulator 20, a conductor 21, and a conductor 22.

In this specification, the expression “a capacitor has a trench” means that a capacitor is formed in a trench (groove) with an aspect ratio (=H/R) of 1 or more as illustrated in FIG. 2B or FIG. 2D.

A capacitor with a trench can have a larger capacitance by increasing the depth of the trench. When trenches are formed in one layer, the trenches have the same depth; hence, the number of trenches needs to be increased to increase the capacitance. In FIGS. 2A to 2D, the capacitor C1 has one trench, whereas the capacitor C2 has four trenches. Note that FIGS. 2A to 2D show examples, and the number and arrangement of trenches are not limited to those shown in FIGS. 2A to 2D.

### <CPU 11>

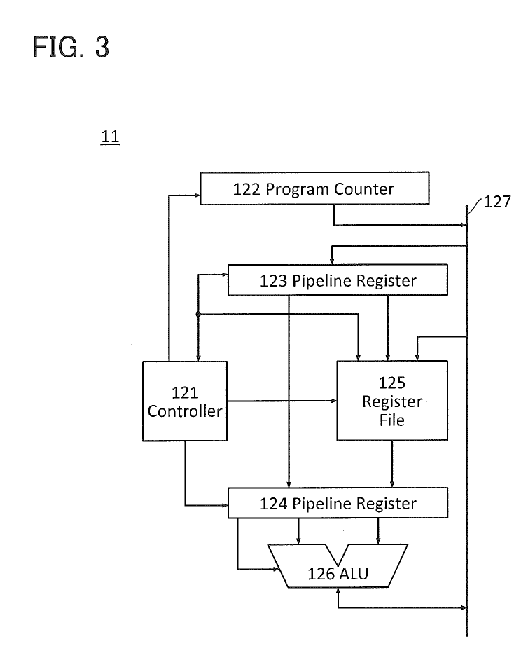

Next, a structure example of the CPU 11 will be described with reference to FIG. 3. The CPU 11 includes a controller 121, a program counter 122, a pipeline register 123, a pipeline register 124, a register file 125, an arithmetic logic unit (ALU) 126, and a data bus 127. Data is exchanged between the CPU 11 and the data memory 12, the program memory 13, the peripheral circuit 14, and the like through the data bus 127.

The controller 121 has a function of decoding and executing instructions contained in a program such as input applications by controlling the overall operations of the program counter 122, the pipeline register 123, the pipeline register 124, the register file 125, the ALU 126, and the data bus 127. The ALU 126 has a function of performing a variety of arithmetic operations such as four arithmetic processes and logic operations. The program counter 122 is a register having a function of storing the address of an instruction to be executed next. The pipeline register 123 has a function of temporarily storing instruction data. The register file 125 includes a plurality of registers (including a general purpose register) and can store data that is read from the main memory, data obtained as a result of arithmetic operations in the ALU 126, or the like. The pipeline register 124 has a function of temporarily storing data used for arithmetic operations performed in the ALU 126, data obtained as a result of arithmetic operations in the ALU 126, or the like.

### <Peripheral Circuit 14>

A variety of circuits can be used for the peripheral circuit 14. For example, a timer, an analog-to-digital (A/D) converter, or a clock generator can be used for the peripheral circuit 14.

Other than the above, a variety of circuits can be provided in the peripheral circuit 14 in accordance with the intended use. For example, when the MCU 10 is used in an electric vehicle or a hybrid electric vehicle, the peripheral circuit 14 can be provided with a motor control circuit for controlling a motor in driving, a regenerative control circuit for obtaining regenerative energy from the motor, and the like.

In an example where the MCU 10 is used in a vehicle with an automatic driving system, the peripheral circuit 14 can be provided with a video display interface, a video input interface, a video code module (compatible with various video coding standards, such as H.265 and H.264/MPEG-4 AVC), a video image processing circuit (performing gamma correction, rotation, color space conversion, etc.), a real-time image recognition engine, and the like.

### <Data Memory 12>

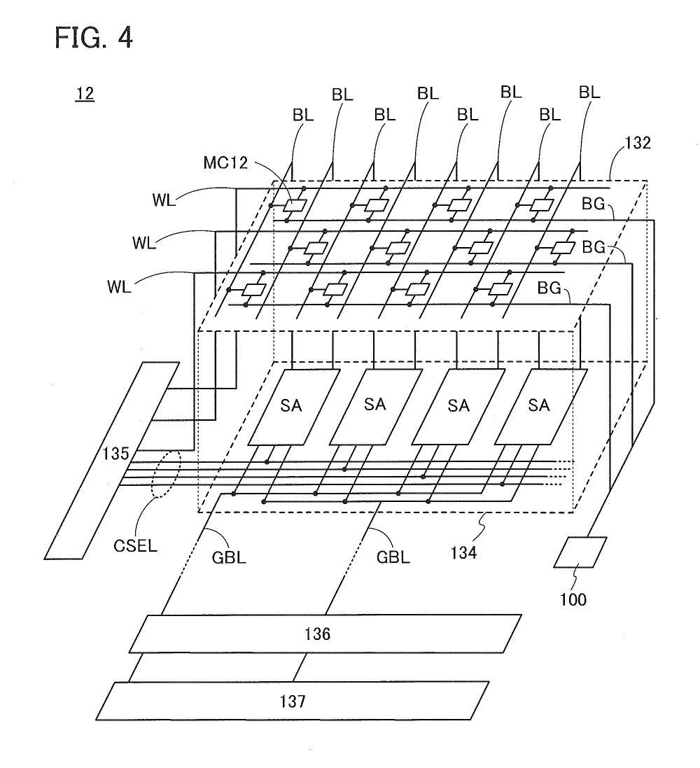

Next, a specific circuit configuration of the data memory 12 will be described with reference to FIGS. 4 to 8 and FIGS. 9A and 9B.

### [Cell Array and Peripheral Circuits]

The data memory 12 in FIG. 4 includes a cell array 132, a sense amplifier circuit 134, a driver circuit 135, a main amplifier 136, an input/output circuit 137, and a circuit 100. The cell array 132 includes a plurality of memory cells MC12. Each of the memory cells MC12 is connected to the wiring WL and the wiring BL. The memory cells MC12 are selected in accordance with a potential supplied to the wiring WL, and a potential corresponding to data to be written to the memory cells MC12 (hereinafter also referred to as writing potential) is supplied to the wiring BL; in this manner, data is written to the memory cells MC12.

The cell array 132 can employ a folded architecture, an open architecture, or the like. With a folded architecture, noise generated in a reading potential output to the wiring BL can be reduced owing to a change in the potential of the wiring WL. With an open architecture, the density of the memory cells MC12 can be higher than that with a folded architecture, and thus the area of the cell array 132 can be reduced. FIG. 4 illustrates a structure example of the cell array 132 with a folded architecture. In the cell array 132 in FIG. 4, the memory cell MC12 connected to one wiring BL and the memory cell MC12 connected to a wiring BL adjacent to the one wiring BL are not connected to the same wiring WL.

The sense amplifier circuit 134 is connected to a plurality of wirings BL and a plurality of wirings GBL. The sense amplifier circuit 134 has functions of amplifying a signal that is input and controlling output of the amplified signal. Specifically, the sense amplifier circuit 134 has a function of amplifying the potential of the wiring BL that corresponds to data stored in the memory cell MC12 (hereinafter the potential is also referred to as reading potential) and outputting it to the wiring GBL at a predetermined timing. Since the reading potential is amplified by the sense amplifier circuit 134, data can be surely read even when a potential read from the memory cell MC12 is extremely low.

The sense amplifier circuit 134 includes a plurality of sense amplifiers SA. The sense amplifier SA has a function of amplifying a difference between a reference potential and a reading potential supplied to the wiring BL and holding the amplified potential difference. The sense amplifier SA also has a function of controlling output of the amplified potential to the wiring GBL. In the example shown here, the sense amplifier SA is connected to two wirings BL and two wirings GBL.

In one embodiment of the present invention, the memory cells MC12 and the sense amplifiers SA are formed in different layers. In particular, the memory cells MC12 are preferably formed on a layer over the sense amplifiers SA. At least one memory cell MC12 is preferably positioned so as to overlap the sense amplifier SA, in which case the area of the data memory 12 can be smaller than that when the memory cells MC12 and the sense amplifiers SA are positioned in the same layer. Thus, the memory capacity per unit area of the data memory 12 can be increased. When all the memory cells MC12 are positioned so as to overlap the sense amplifier SA, the area of the data memory 12 can be further reduced. The memory cell MC12 may be positioned so as to overlap one sense amplifier SA, or alternatively be positioned so as to overlap several sense amplifiers SA.

Since the memory cells MC12 and the sense amplifiers SA are stacked, the length of the wirings BL that connect the memory cells MC12 to the sense amplifiers SA can be reduced. Consequently, the wiring resistance of the wirings BL can be low, and a reduction in power consumption and an increase in operating speed of the data memory 12 can be achieved. Furthermore, the area of the capacitors provided in the memory cells MC12 can be small; thus, the size of the memory cells MC12 can be small.

The main amplifier 136 is connected to the sense amplifier circuit 134 and the input/output circuit 137. The main amplifier 136 has a function of amplifying a signal that is input. Specifically, the main amplifier 136 has a function of amplifying the potential of the wiring GBL and outputting it to the input/output circuit 137. Note that the main amplifier 136 is not necessarily provided.

The input/output circuit 137 has a function of outputting the potential of the wiring GBL or a potential output from the main amplifier 136 as reading data to the outside.

The driver circuit 135 is connected to the memory cells MC12 through the wirings WL. The driver circuit 135 has a function of supplying a signal for selecting the memory cells MC12 to which data is written (hereinafter the signal is also referred to as write word signal) to the wiring WL. The driver circuit 135 can be configured with a decoder or the like.

The data memory 12 is capable of selecting a signal to be output to the outside with the use of the sense amplifiers SA and wirings CSEL. Therefore, the input/output circuit 137 does not need a function of selecting a signal with the use of a multiplexer or the like, and thus can have a simple circuit configuration and a small occupied area.

Note that the number of the wirings GBL is not particularly limited and can be a given number smaller than the number of the wirings BL in the cell array 132.

The memory cells MC12 are connected to the circuit 100 through the wirings BG. The circuit 100 has a function of controlling the potential of the second gate of the transistor OS1 included in each memory cell MC12 connected to the wiring BG.

The circuit 100 is capable of supplying a negative potential the second gate of the transistor OS1 and holing the potential. The circuit 100 enables the reduction in cutoff current of the transistor OS1, thereby decreasing power consumption of the data memory 12.

### [Sense Amplifier SA]

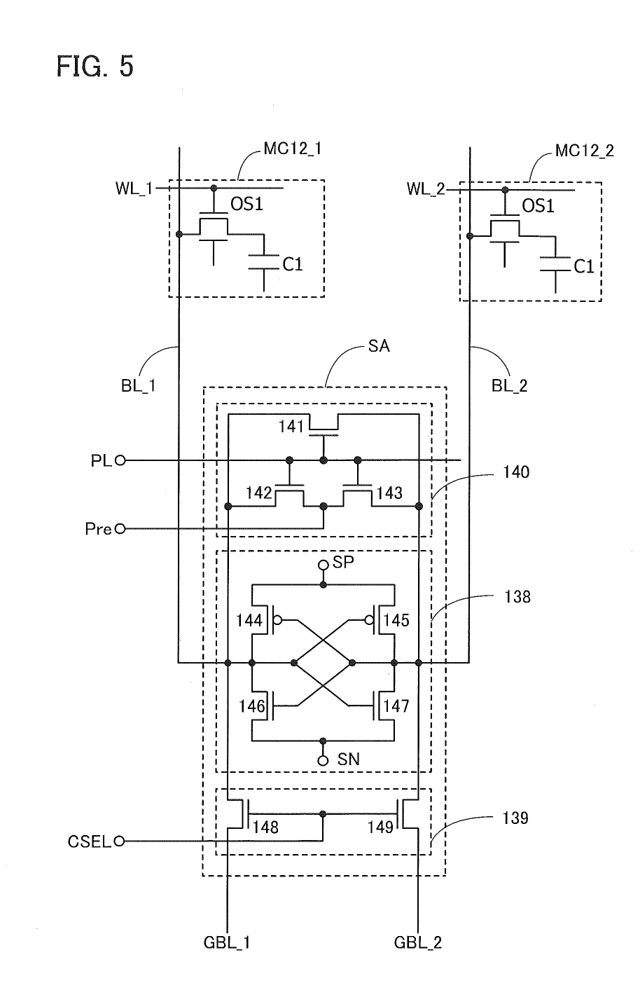

A specific configuration example of the sense amplifier SA will be described. FIG. 5 illustrates an example of a circuit configuration of the memory cells MC12 and the sense amplifier SA electrically connected to the memory cells MC12. The memory cells MC12 are connected to the sense amplifier SA through the wirings BL. In the example shown here, a memory cell MC12_1 is connected to the sense amplifier SA through a wiring BL_1, and a memory cell MC12_2 is connected to the sense amplifier SA through a wiring BL_2.

Although one memory cell MC12 is connected to one wiring BL in the example of FIG. 5, a plurality of memory cells MC12 may be connected to one wiring BL.

The sense amplifier SA includes an amplifier circuit 138, a switch circuit 139, and a precharge circuit 140.

The amplifier circuit 138 includes p-channel transistors 144 and 145 and n-channel transistors 146 and 147. One of a source and a drain of the transistor 144 is connected to a wiring SP, and the other thereof is connected to a gate of the transistor 145, a gate of the transistor 147, and the wiring BL_1. One of a source and a drain of the transistor 146 is connected to the gate of the transistor 145, the gate of the transistor 147, and the wiring BL_1, and the other thereof is connected to a wiring SN. One of a source and a drain of the transistor 145 is connected to the wiring SP, and the other thereof is connected to a gate of the transistor 144, a gate of the transistor 146, and the wiring BL_2. One of a source and a drain of the transistor 147 is connected to the gate of the transistor 144, the gate of the transistor 146, and the wiring BL_2, and the other thereof is connected to the wiring SN. The amplifier circuit 138 has a function of amplifying the potential of the wiring BL_1 and the potential of the wiring BL_2. In FIG. 5, the sense amplifier SA including the amplifier circuit 138 functions as a latch sense amplifier.

The switch circuit 139 includes n-channel transistors 148 and 149. The transistors 148 and 149 may be p-channel transistors. One of a source and a drain of the transistor 148 is connected to the wiring BL_1, and the other thereof is connected to a wiring GBL_1. One of a source and a drain of the transistor 149 is connected to the wiring BL_2, and the other thereof is connected to a wiring GBL_2. Gates of the transistor 148 and the transistor 149 are connected to the wiring CSEL. The switch circuit 139 has a function of controlling electrical continuity between the wiring BL_1 and the wiring GBL_1 and electrical continuity between the wiring BL_2 and the wiring GBL_2 on the basis of a potential supplied to the wiring CSEL.

The precharge circuit 140 includes n-channel transistors 141, 142, and 143. The transistors 141 to 143 may be p-channel transistors. One of a source and a drain of the transistor 142 is connected to the wiring BL_1, and the other thereof is connected to a wiring Pre. One of a source and a drain of the transistor 143 is connected to the wiring BL_2, and the other thereof is connected to the wiring Pre. One of a source and a drain of the transistor 141 is connected to the wiring BL_1, and the other thereof is connected to the wiring BL_2. Gates of the transistors 141 to 143 are connected to a wiring PL. The precharge circuit 140 has a function of initializing the potentials of the wiring BL_1 and the wiring BL_2.

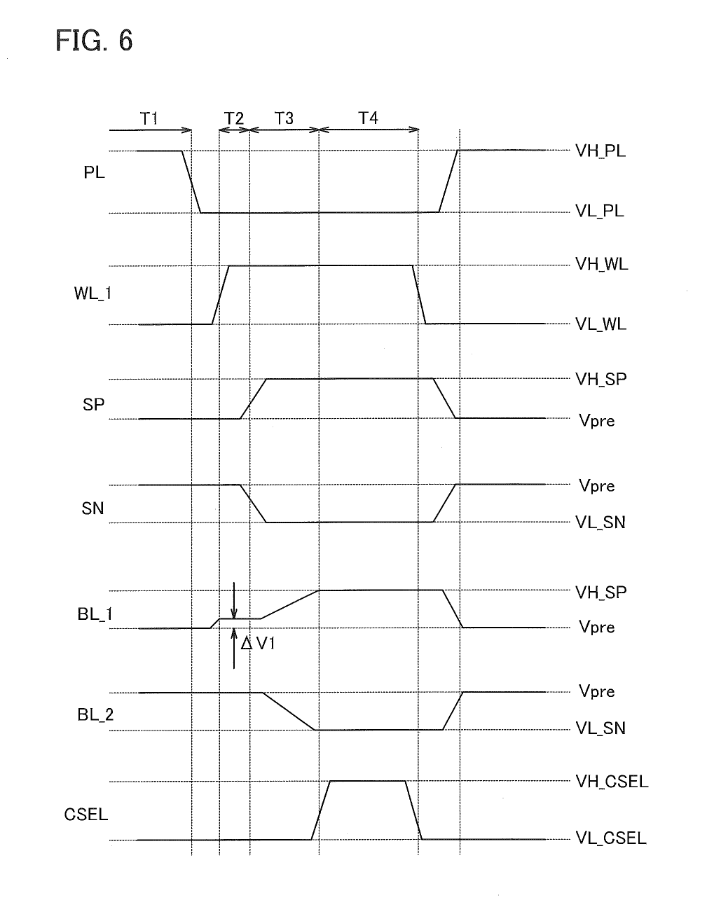

Next, operation examples of the memory cells MC12 and the sense amplifier SA illustrated in FIG. 5 in data reading will be described with reference to a timing chart of FIG. 6.

First, in a period T1, the transistors 141 to 143 included in the precharge circuit 140 are turned on, so that the potentials of the wirings BL_1 and BL_2 are initialized. Specifically, a high-level potential VH_PL is supplied to the wiring PL to turn on the transistors 141 to 143 in the precharge circuit 140. Accordingly, a potential Vpre of the wiring Pre is supplied to the wirings BL_1 and BL_2. Note that the potential Vpre can be, for example, (VH_SP+VL_SN)/2.

In the period T1, a low-level potential VL_CSEL is supplied to the wiring CSEL, and accordingly, the transistors 148 and 149 in the switch circuit 139 are off. A low-level potential VL_WL is supplied to the wiring WL_1, and accordingly, the transistor OS1 in the memory cell MC12_1 is off. The low-level potential VL_WL is also supplied to the wiring WL_2 (not shown in FIG. 6), and thus the transistor OS1 in the memory cell MC12_2 is off. The potential Vpre is supplied to the wirings SP and SN, and accordingly, the amplifier circuit 138 is off.

Then, a low-level potential VL_PL is supplied to the wiring PL to turn off the transistors 141 to 143 in the precharge circuit 140. Then, in a period T2, the wiring WL_1 is selected. Specifically, in FIG. 6, a high-level potential VH_WL is supplied to the wiring WL_1 to select the wiring WL_1 and turn on the transistor OS1 in the memory cell MC12_1. Thus, electrical continuity is established between the wiring BL_1 and the capacitor C1 through the transistor OS1. When electrical continuity is established between the wiring BL_1 and the capacitor C1, the potential of the wiring BL_1 changes in accordance with the amount of charge held in the capacitor C1.

The timing chart in FIG. 6 shows an example where the amount of charge accumulated in the capacitor C1 is large. Specifically, when the amount of charge accumulated in the capacitor C1 is large, charge is released from the capacitor C1 to the wiring BL_1, so that the potential of the wiring BL_1 rises from the potential Vpre by ΔV1. Meanwhile, when the amount of charge accumulated in the capacitor C1 is small, charge flows from the wiring BL_1 to the capacitor C1, so that the potential of the wiring BL_1 falls by ΔV2.

In the period T2, the low-level potential VL_CSEL continues to be supplied to the wiring CSEL, and thus the transistors 148 and 149 in the switch circuit 139 remain off. The potential Vpre continues to be supplied to the wirings SP and SN, and thus the sense amplifier SA remains off.

Next, in a period T3, the high-level potential VH_SP is supplied to the wiring SP and the low-level potential VL_SN is supplied to the wiring SN, whereby the amplifier circuit 138 is turned on. The amplifier circuit 138 has a function of amplifying a potential difference between the wirings BL_1 and BL_2 (ΔV1 in FIG. 6). Accordingly, in the timing chart of FIG. 6, turning on the amplifier circuit 138 makes the potential of the wiring BL_1 increase from the potential Vpre+ΔV1 toward the potential VH_SP of the wiring SP, and makes the potential of the wiring BL_2 fall from the potential Vpre toward the potential VL_SN of the wiring SN.

Note that in the case where the potential of the wiring BL_1 is Vpre−ΔV2 at the beginning of the period T3, turning on the amplifier circuit 138 makes the potential of the wiring BL_1 fall from the potential Vpre−ΔV2 toward the potential VL_SN of the wiring SN, and makes the potential of the wiring BL_2 rise from the potential Vpre toward the potential VH_SP of the wiring SP.

In the period T3, the low-level potential VL_PL continues to be supplied to the wiring PL, so that the transistors 141 to 143 in the precharge circuit 140 remain off. The low-level potential VL_CSEL continues to be supplied to the wiring CSEL, and thus, the transistors 148 and 149 in the switch circuit 139 remain off. The high-level potential VH_WL continues to be supplied to the wiring WL_1; thus, the transistor OS1 in the memory cell MC12_1 remains on. Consequently, charge corresponding to the potential VH_SP of the wiring BL_1 is accumulated in the capacitor C1 in the memory cell MC12_1.

Next, in a period T4, the potential supplied to the wiring CSEL is changed to turn on the switch circuit 139. Specifically, in FIG. 6, a high-level potential VH_CSEL is supplied to the wiring CSEL, so that the transistors 148 and 149 in the switch circuit 139 are turned on. Thus, the potential of the wiring BL_1 is supplied to the wiring GBL 1, and the potential of the wiring BL_2 is supplied to the wiring GBL_2.

In the period T4, the low-level potential VL_PL continues to be supplied to the wiring PL, so that the transistors 141 to 143 in the precharge circuit 140 remain off. The high-level potential VH_WL continues to be supplied to the wiring WL_1; thus, the transistor OS1 in the memory cell MC12_1 remains on. The high-level potential VH_SP continues to be supplied to the wiring SP and the low-level potential VL_SP continues to be supplied to the wiring SN; thus, the amplifier circuit 138 remains on. Accordingly, in the memory cell MC12_1, the charge that is accumulated in the capacitor C1 and corresponds to the potential VH_SP of the wiring BL_1 remains there.

When the period T4 is over, the potential supplied to the wiring CSEL is changed to turn off the switch circuit 139. Specifically, in FIG. 6, the low-level potential VL_CSEL is supplied to the wiring CSEL, so that the transistors 148 and 149 in the switch circuit 139 are turned off.

Furthermore, when the period T4 is over, the wiring WL_1 is deselected. Specifically, in FIG. 6, the low-level potential VL_WL is supplied to the wiring WL_1, whereby the wiring WL_1 is deselected and the transistor OS1 in the memory cell MC12_1 is turned off. Consequently, the charge corresponding to the potential VH_SP of the wiring BL_1 is held in the capacitor C1; thus, the data is held in the memory cell MC12_1 even after the data is read out.

Through the operations in the periods T1 to T4, data is read from the memory cell MC12_1. Data in the memory cell MC12_2 can be read in a similar manner.

Note that data can be written to the memory cell MC12 on the basis of the above principle. Specifically, as in data reading, first, the transistors 141 to 143 in the precharge circuit 140 are temporarily turned on to initialize the potentials of the wirings BL_1 and BL_2. Then, the wiring WL_1 connected to the memory cell MC12_1 to which data is to be written or the wiring WL_2 connected to the memory cell MC12_2 to which data is to be written is selected, and the transistor OS1 in the memory cell MC12_1 or the memory cell MC12_2 is turned on. Thus, electrical continuity is established between the wiring BL_1 or the wiring BL_2 and the capacitor C1 through the transistor OS1. Next, the high-level potential VH_SP is supplied to the wiring SP and the low-level potential VL_SN is supplied to the wiring SN to turn on the amplifier circuit 138. The potential supplied to the wiring CSEL is then changed to turn on the switch circuit 139. Specifically, the high-level potential VH_CSEL is supplied to the wiring CSEL, so that the transistors 148 and 149 in the switch circuit 139 are turned on. Consequently, electrical continuity is established between the wirings BL_1 and GBL_1 and between the wirings BL_2 and GBL_2. Then, writing potentials are supplied to the wirings GBL_1 and GBL_2, whereby the writing potentials are supplied to the wirings BL_1 and BL_2 through the switch circuit 139. Thus, charge is accumulated in the capacitor C1 in accordance with the potential of the wiring BL_1 or the wiring BL_2; hence, data is written to the memory cell MC12_1 or the memory cell MC12_2.

After the potential of the wiring GBL_1 is supplied to the wiring BL_1 and the potential of the wiring GBL_2 is supplied to the wiring BL_2, the relation in level between the potential of the wiring BL_1 and the potential of the wiring BL_2 is maintained by the amplifier circuit 138 as long as the sense amplifier SA is on even after the transistors 148 and 149 in the switch circuit 139 are turned off. Therefore, the timing of turning off the transistors 148 and 149 in the switch circuit 139 may be either before or after the selection of the wiring WL_1.

### [Circuit 100]

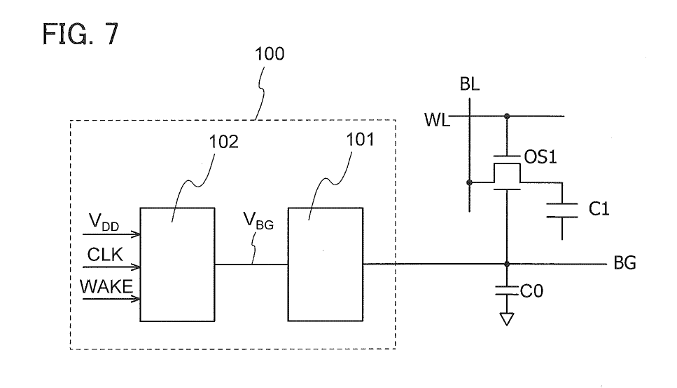

Next, the circuit 100 will be described in detail. The circuit 100 illustrated in FIG. 7 is a semiconductor device for driving the second gate of the transistor OS1. The circuit 100 includes a voltage generator circuit 102 and a voltage retention circuit 101. The circuit 100 has a function of writing a potential to the second gate of the transistor OS1 and holding the potential.

For example, when a negative potential is written to the second gate of the transistor OS1 by the circuit 100, Vₜₕ of the transistor OS1 can be kept high while the negative potential of the second gate is held. Keeping Vₜₕ of the transistor OS1 high can prevent the transistor OS1 from having normally-on characteristics.

The voltage retention circuit 101 has a function of applying a potential V_{BG} generated in the voltage generator circuit 102 to the second gate of the transistor OS1 and holding the potential.

The voltage generator circuit 102 has a function of generating V_{BG} from GND or V_{DD}. The voltage generator circuit 102 is supplied with V_{DD}, a signal CLK, and a signal WAKE. The signal CLK is a clock signal and is used to operate the voltage generator circuit 102. The signal WAKE has a function of controlling input of the signal CLK to the voltage generator circuit 102. For example, when an H-level signal is supplied as the signal WAKE, the signal CLK is input to the voltage generator circuit 102, and the voltage generator circuit 102 generates V_{BG}.

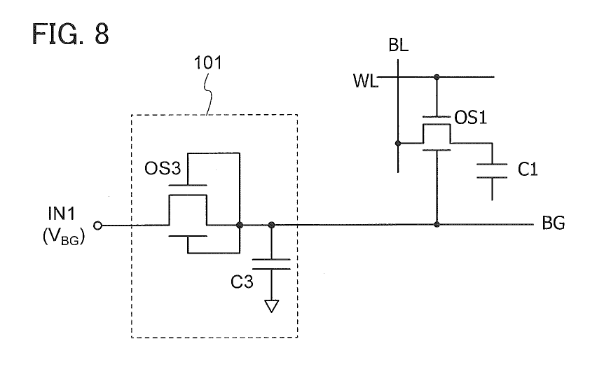

Next, the voltage retention circuit 101 will be described in detail. The voltage retention circuit 101 illustrated in FIG. 8 includes a transistor OS3 and a capacitor C3. A first electrode of the transistor OS3 is electrically connected to a first gate and a second gate of the transistor OS3, a first electrode of the capacitor C3, and the wiring BG. A second electrode of the capacitor C3 is connected to GND. A second electrode of the transistor OS3 is electrically connected to an input terminal IN1. The input terminal IN1 is electrically connected to the voltage generator circuit 102 and supplied with the potential V_{BG}.

In the voltage retention circuit 101, the transistor OS3 functions as a diode. The transistor OS3 also has a function of writing a potential to the wiring BG and holding the potential.

When a negative potential is supplied to the input terminal Ni, the transistor OS3 is turned on, and the negative potential is also written to the wiring BG. Then, by setting the input terminal Ni to GND, V_{G} of the transistor OS3 becomes 0 V and the transistor OS3 is turned off. Thus, the negative potential written to the wiring BG is held, and the transistor OS1 can keep on having normally-off characteristics.

The transistor OS3 is preferably a transistor with a low off-state current. As the transistor with a low off-state current, an OS transistor or a transistor containing a wide-bandgap semiconductor in a channel formation region is preferably used. The use of the above transistor as the transistor OS3 enables the voltage retention circuit 101 to retain a potential written to the wiring BG for a long time.

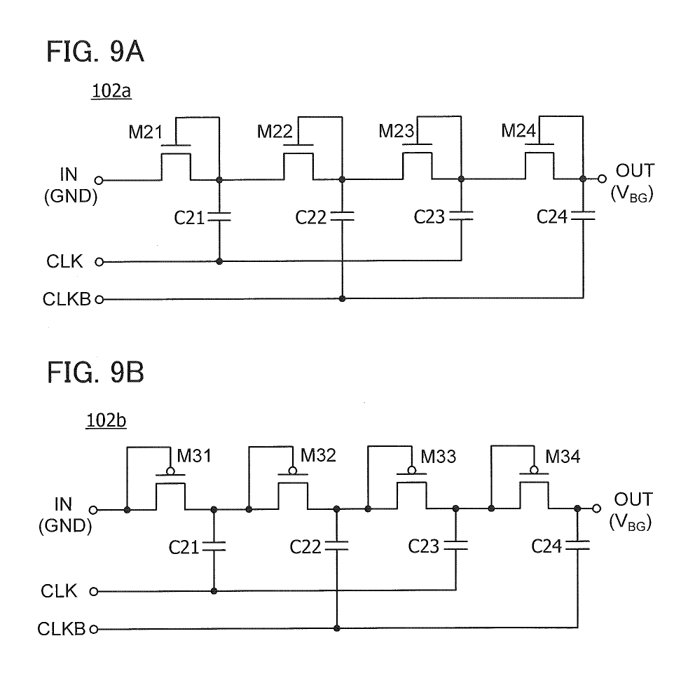

Next, the voltage generator circuit 102 will be described in detail. Circuit diagrams in FIGS. 9A and 9B show examples of the voltage generator circuit 102. These circuits are step-down charge pumps; GND is input to the input terminal IN, and V_{BG} that is a negative potential is output from an output terminal OUT. The number of stages of fundamental circuits in the charge pump circuit is four in the examples shown here; however, it is not limited to this, and the charge pump circuit may be configured with given stages of fundamental circuits.

As illustrated in FIG. 9A, a voltage generator circuit 102a includes transistors M21 to M24 and capacitors C21 to C24. The transistors M21 to M24 are assumed as n-channel transistors in the following description.

The transistors M21 to M24 are connected in series between the input terminal IN and the output terminal OUT, and each has a structure in which a gate and a first electrode are connected so as to function as a diode. The capacitors C21 to C24 are connected to the gates of the transistors M21 to M24, respectively.

The signal CLK is input to first electrodes of the capacitors C21 and C23 in the odd-numbered stages, and a signal CLKB is input to first electrodes of the capacitors C22 and C24 in the even-numbered stages. The signal CLKB is an inverted clock signal obtained by phase inversion of the signal CLK.

The voltage generator circuit 102a has a function of stepping down GND input to the input terminal IN and generating V_{BG}. The voltage generator circuit 102a can generate a negative potential only by supply of the signals CLK and CLKB.

The voltage generator circuit 102 may be formed of p-channel transistors. A voltage generator circuit 102b illustrated in FIG. 9B includes p-channel transistors M31 to M34.

### <Program Memory 13>

As a specific circuit configuration of the program memory 13, the circuit configuration of the data memory 12 explained using FIGS. 4 to 8 and FIGS. 9A and 9B can be used without any change.

The MCU 10 with the above structure can achieve low power consumption and enables a low-power MCU system, a low-power semiconductor device, and a novel semiconductor device to be provided.

### Embodiment 2

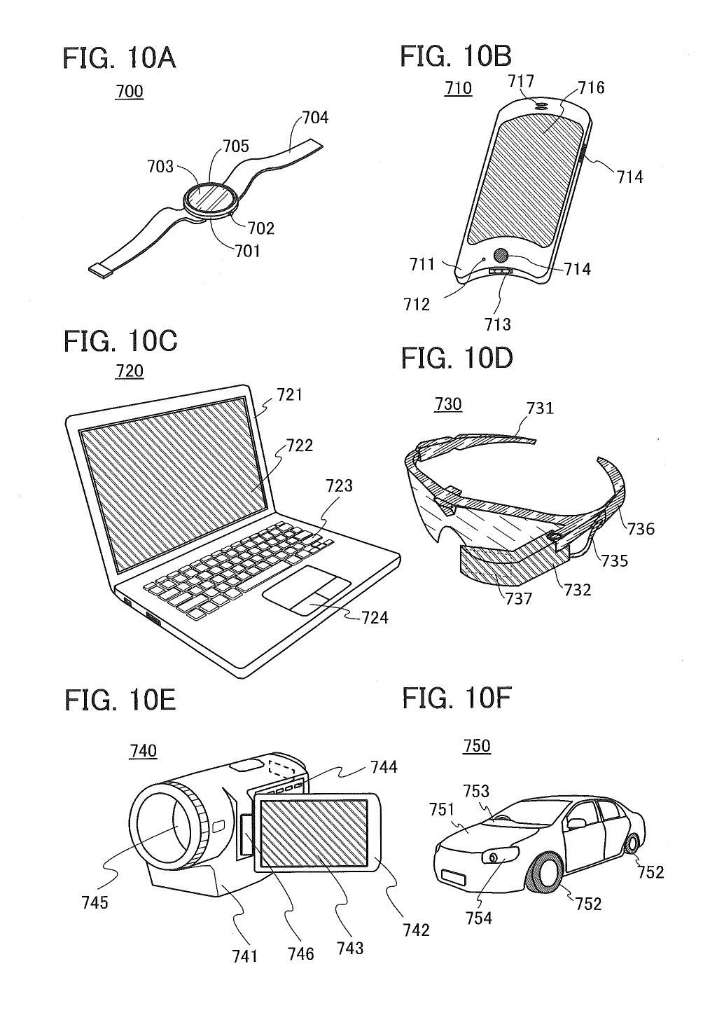

The MCU 10 shown in Embodiment 1 is preferably used in an electronic device incorporating a battery, in which case power consumption of the electronic device can be reduced, and power of the battery can be saved. FIGS. 10A to 10F illustrate specific examples.

FIG. 10A illustrates an example of a wristwatch terminal 700. The wristwatch terminal 700 includes a housing 701, a winding crown 702, a display portion 703, a belt 704, a sensing unit 705, and the like. A battery and the MCU 10 are provided inside the housing 701. The display portion 703 may be provided with a touch panel. A user can input information by using a finger touching the touch panel as a pointer.

The sensing unit 705 has a function of obtaining information by measuring a surrounding state. For example, a camera, an acceleration sensor, a direction sensor, a pressure sensor, a temperature sensor, a humidity sensor, an illuminance sensor, or a global positioning system (GPS) signal receiver circuit can be used as the sensing unit 705.

For example, when an arithmetic device in the housing 701 determines that the ambient light level measured by an illuminance sensor of the sensing unit 705 is sufficiently higher than predetermined illuminance, the luminance of the display portion 703 is lowered. Meanwhile, when the arithmetic device determines that the ambient light level is not sufficiently high, the luminance of the display portion 703 is increased. As a result, power consumption of the electronic device can be reduced.

FIG. 10B illustrates a mobile phone 710. The mobile phone 710 includes a housing 711, a display portion 716, operation buttons 714, an external connection port 713, a speaker 717, a microphone 712, and the like. A battery and the MCU 10 are provided inside the housing 711. When the display portion 716 of the mobile phone 710 is touched with a finger or the like, data can be input to the mobile phone 710. Operations such as making a call and inputting letters can be performed by touch on the display portion 716 with a finger or the like. The power can be turned on or off with the operation button 714. Moreover, types of images displayed on the display portion 716 can be switched with the operation button 714; for example, the screen can be switched from a mail creation screen to a main menu screen.

FIG. 10C illustrates a laptop personal computer 720 including a housing 721, a display portion 722, a keyboard 723, a pointing device 724, and the like. A battery and the MCU 10 are provided inside the housing 721.

FIG. 10D illustrates a goggle-type display 730. The goggle-type display 730 includes temples 731, a housing 732, a cable 735, a battery 736, and a display portion 737. The battery 736 is held in the temple 731. The display portion 737 is provided in the housing 732. The housing 732 incorporates a variety of electronic components such as the MCU 10, a wireless communication device, and a memory device. Power is supplied from the battery 736 through the cable 735 to the display portion 737 and the electronic components in the housing 732. A variety of information such as an image transmitted wirelessly is displayed on the display portion 737.

A camera may be provided in the housing 732 of the goggle-type display 730. A user can operate the goggle-type display 730 owing to the camera, which senses movement of the eye and eyelid of the user. The temple 731 of the goggle-type display 730 may be provided with various sensors such as a temperature sensor, a pressure sensor, an acceleration sensor, and a biosensor. For example, the goggle-type display 730 obtains biological information on the user with a biosensor and stores the information in the memory device of the housing 732. The goggle-type display 730 may transmit biological information to another information appliance with a wireless signal.

FIG. 10E illustrates a video camera 740. The video camera 740 includes a first housing 741, a second housing 742, a display portion 743, an operation key 744, a lens 745, a joint 746, and the like. The operation key 744 and the lens 745 are provided in the first housing 741, and the display portion 743 is provided in the second housing 742. A battery and the MCU 10 are provided inside the first housing 741. The battery may be provided outside the first housing 741. The first housing 741 and the second housing 742 are connected to each other with the joint 746, and the angle between the first housing 741 and the second housing 742 can be changed with the joint 746. Images on the display portion 743 may be switched in accordance with the angle at the joint 746 between the first housing 741 and the second housing 742.

FIG. 10F illustrates an automobile 750. The automobile 750 includes a car body 751, wheels 752, a dashboard 753, lights 754, and the like. A battery and the MCU 10 are provided inside the car body 751.

The MCU 10, a pressure sensor, and a temperature sensor may be provided inside the wheels 752, in which case the automobile 750 is capable of monitoring the tire pressure and temperature of the wheels 752.

### Embodiment 3

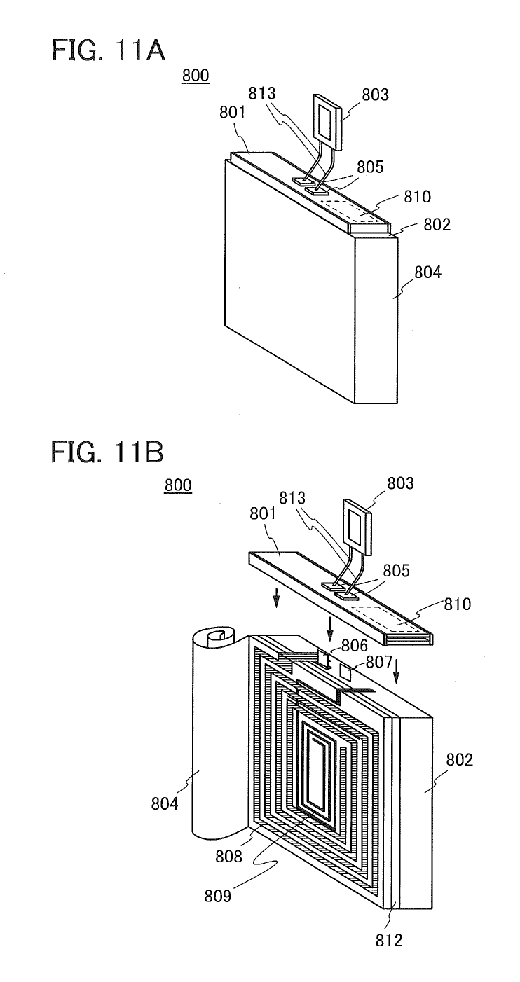

In this embodiment, a wireless sensor including the MCU 10 shown in Embodiment 1 and an application example of the wireless sensor will be described with reference to FIGS. 11A and 11B, FIG. 12, FIG. 13, FIGS. 14A and 14B, and FIG. 15.

### Structure Example 1 of Wireless Sensor

FIGS. 11A and 11B are external views illustrating a structure example of a wireless sensor 800 that is an electronic device of one embodiment of the present invention. The wireless sensor 800 includes a circuit board 801, a battery 802, and a sensor 803. A label 804 is attached to the battery 802. Furthermore, as illustrated in FIG. 11B, the wireless sensor 800 includes a terminal 806, a terminal 807, an antenna 808, and an antenna 809.

The circuit board 801 is provided with terminals 805 and an integrated circuit 810. The terminals 805 are connected to the sensor 803 via wirings 813. Note that the number of the terminals 805 is not limited to two and is determined in accordance with the need.

Furthermore, the circuit board 801 may be provided with a semiconductor element such as a transistor or a diode, a resistor, a wiring, or the like.

In the case where heat generated by the battery 802 or an electromagnetic field generated by the antennas 808 and 809 adversely affects the operation of the sensor 803, the length of the wiring 813 is extended so that the sensor 803 is apart from the battery 802 or the antennas 808 and 809. The length of the wiring 813 ranges, for example, from 1 cm to 1 m, preferably from 1 cm to 50 cm, further preferably from 1 cm to 30 cm.

Unless the heat or electromagnetic field affects the sensor 803, the sensor 803 can be provided directly on the circuit board 801 without providing the wiring 813.

The shape of each of the antennas 808 and 809 is not limited to a coil shape and may be a linear shape or a plate shape, for example. Moreover, a planar antenna, an aperture antenna, a traveling-wave antenna, an EH antenna, a magnetic-field antenna, or a dielectric antenna may be used. Alternatively, the antenna 808 or the antenna 809 may be a flat-plate conductor. The flat-plate conductor can serve as one of conductors for electric field coupling. That is, the antenna 808 or the antenna 809 can serve as one of two conductors of a capacitor. Thus, power can be transmitted and received not only by an electromagnetic field or a magnetic field but also by an electric field.

The integrated circuit 810 includes a circuit formed using a Si transistor or an OS transistor. The MCU 10 shown in Embodiment 1 can be used for the integrated circuit 810.

The line width of the antenna 808 is preferably larger than that of the antenna 809. This makes it possible to increase the amount of power received by the antenna 808.

The sensor 803 is a circuit having a function of outputting various kinds of data such as thermal, mechanical, and electromagnetic data, as analog data.

The wireless sensor 800 includes a layer 812 between the battery 802 and the antennas 808 and 809. The layer 812 has, for example, a function of blocking an electromagnetic field that is generated by the battery 802. A magnetic material can be used for the layer 812, for example.

Using the MCU 10 shown in Embodiment 1 in the wireless sensor 800 can reduce power consumption of the wireless sensor 800.

### Structure Example 2 of Wireless Sensor

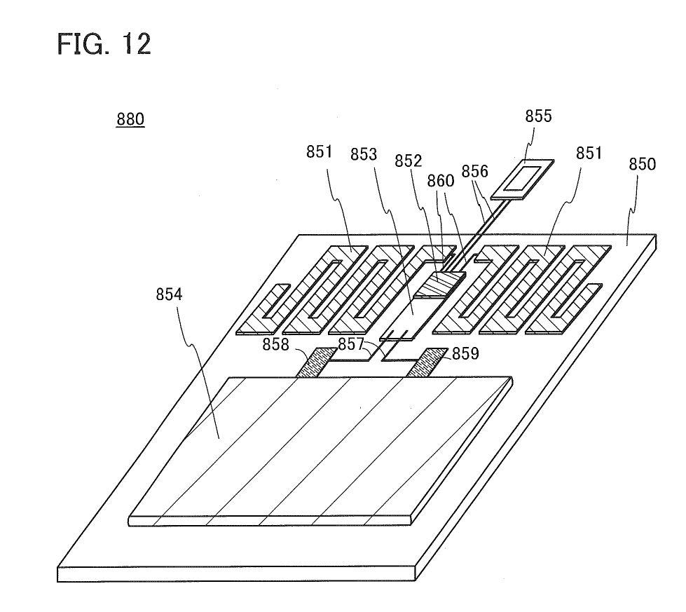

FIG. 12 is an external view illustrating a structure example of a wireless sensor 880 that is an electronic device of one embodiment of the present invention. The wireless sensor 880 includes a support 850, an antenna 851, an integrated circuit 852, a circuit board 853, a sensor 855, and a battery 854.

The circuit board 853 is provided with the integrated circuit 852. Furthermore, the circuit board 853 may also be provided with a semiconductor element such as a transistor or a diode, a resistor, a wiring, or the like.

The integrated circuit 852 includes a circuit formed using a Si transistor or an OS transistor. The MCU 10 shown in Embodiment 1 can be used for the integrated circuit 852.

The antenna 851 is connected to the integrated circuit 852 via a wiring 860. For the details of the antenna 851, the description of the antenna 808 or the antenna 809 of the wireless sensor 800 can be referred to.

The sensor 855 is connected to the integrated circuit 852 via a wiring 856. The sensor 855 may be formed outside the support 850 or over the support 850.

The sensor 855 is a circuit having a function of outputting various kinds of data such as thermal, mechanical, and electromagnetic data, as analog data.

The battery 854 includes a terminal 858 having a function of one of a positive electrode and a negative electrode, and a terminal 859 having a function of the other of the positive electrode and the negative electrode. Each of the terminals is connected to the integrated circuit 852 via a wiring 857 and the circuit board 853.

The support 850 can be formed using glass, quartz, plastic, metal, stainless steel foil, tungsten foil, a flexible substrate, an attachment film, a base film, paper containing a fibrous material, or wood, for example. Examples of a flexible substrate include flexible synthetic resin substrates made of plastics typified by polyethylene terephthalate (PET), polyethylene naphthalate (PEN), and polyether sulfone (PES), and acrylic. Examples of an attachment film include attachment films formed using polypropylene, polyester, polyvinyl fluoride, polyvinyl chloride, and the like. Examples of a base film include films formed using polyester, polyamide, polyimide, aramid, and epoxy, an inorganic vapor deposition film, and paper.

The wireless sensor 880 is preferably thin. In particular, the thickness of the wireless sensor 880 including the thickness of the battery 854 and the support 850 ranges preferably from 0.1 mm to 5 mm, further preferably from 0.1 mm to 3 mm, still further preferably from 0.1 mm to 1 mm. The wireless sensor 880 with the above thickness can be embedded in paper such as a poster or corrugated cardboard.

Furthermore, the wireless sensor 880 is preferably flexible. In particular, it is preferred that the support 850 and the battery 854 can change their shape at a curvature radius of 30 mm or more, preferably 10 mm or more. The wireless sensor 880 having the above structure can be attached to clothing or a human body.

In order to obtain the above structure, the battery 854 is preferably thin and flexible. As an exterior body of the battery 854, a film with a three-layer structure including a first thin film, a second thin film, and a third thin film formed in this order can be used, for example. The third thin film has a function as the outer surface of the exterior body. Examples of a material for the first thin film include polyethylene, polypropylene, polycarbonate, ionomer, and polyamide. Examples of the second thin film include highly flexible thin metal films of aluminum, stainless steel, copper, nickel, and the like. Examples of the third thin film include insulating synthetic resin films of a polyamide-based resin, a polyester-based resin, and the like.

Using the MCU 10 shown in Embodiment 1 in the wireless sensor 880 can reduce power consumption of the wireless sensor 880.

### Application Examples of Wireless Sensor

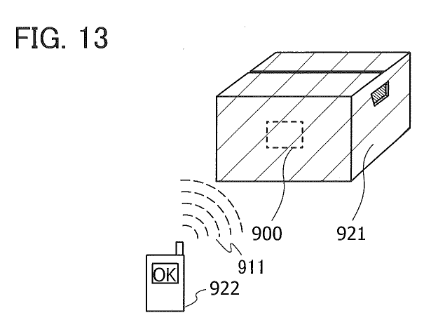

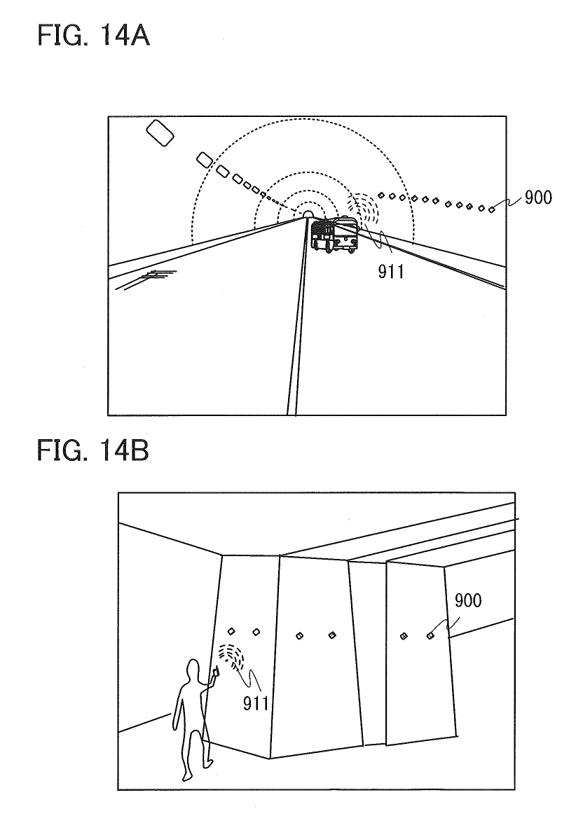

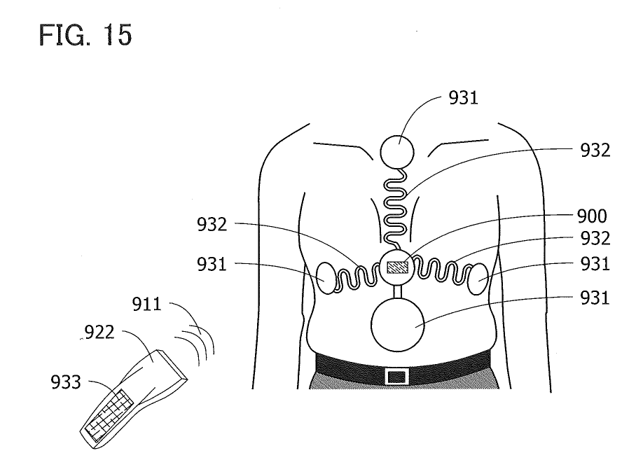

Next, application examples of the aforementioned wireless sensors will be described with reference to FIG. 13, FIGS. 14A and 14B, and FIG. 15. As a wireless sensor 900 shown in FIG. 13, FIGS. 14A and 14B, and FIG. 15, the wireless sensor 800 or the wireless sensor 880 described above can be used.

An application form of the wireless sensor can be described with a schematic diagram of FIG. 13. The wireless sensor 900 is attached to or incorporated in an item 921, and a radio signal 911 is sent from an external reader 922. The wireless sensor 900 that has received the radio signal 911 can obtain data of a temperature or the like without touching the item 921, owing to its sensing function, and send the data to the reader 922.

Another application form of the wireless sensor can be described using a schematic view of FIG. 14A. For example, the wireless sensor 900 is embedded in a tunnel wall surface, and the radio signal 911 is sent externally. The wireless sensor 900 that has received the radio signal 911 can obtain data on the tunnel wall surface by the sensing function and send the data.

Another application form of the wireless sensor can be described with reference to a schematic diagram of FIG. 14B. For example, the wireless sensor 900 is embedded in a wall surface of a bridge pillar, and the radio signal 911 is sent externally. The wireless sensor 900 that has received the radio signal 911 can obtain data in the bridge pillar by the sensing function and send the data.

Another application form of the wireless sensor can be described with a schematic diagram of FIG. 15. For example, the wireless sensor 900 is attached to a human body with the use of a bond pad or the like, and the radio signal 911 is sent from a reader 922. The wireless sensor 900 that has received the radio signal 911 can obtain data such as biological data by supplying a signal through a wiring 932 to an electrode 931 or the like attached to the human body, and send the data. The obtained data can be checked on a display portion 933 of the reader 922.

The wireless sensor 900 illustrated in FIG. 13, FIGS. 14A and 14B, and FIG. 15 achieves low power consumption by including the MCU 10 shown in Embodiment 1.

### Embodiment 4

In this embodiment, structure examples of the MCU 10 shown in Embodiment 1 will be described.

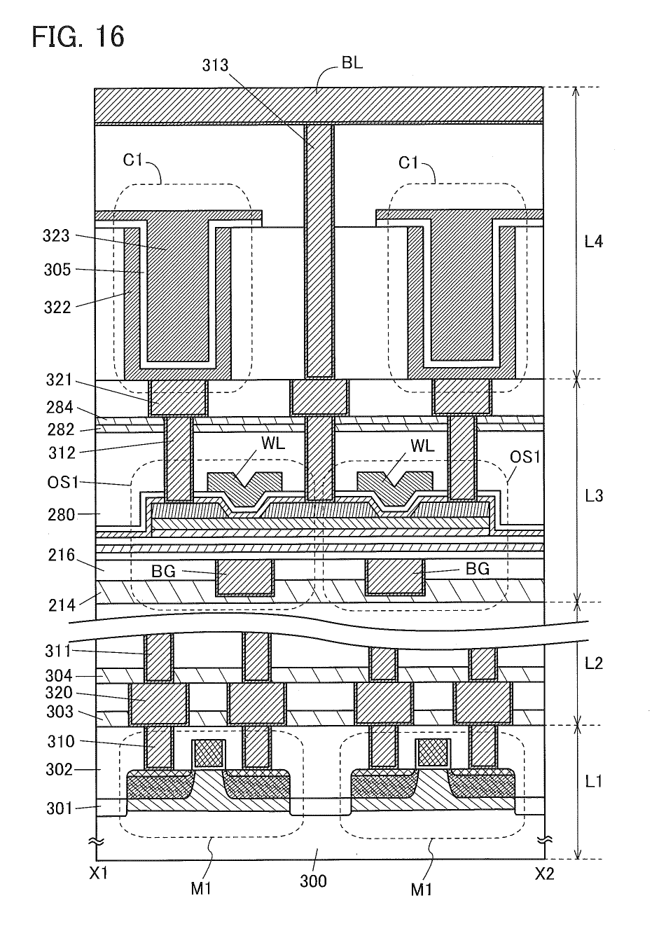

FIG. 16 illustrates an example of a cross-sectional view of the MCU 10. The MCU 10 illustrated in FIG. 16 includes a transistor M1, the transistor OS1, and the capacitor C1.

The MCU 10 in FIG. 16 includes a layer L1, a layer L2, a layer L3, and a layer L4 that are stacked in this order from the bottom.

The layer L1 includes the transistor M1, a substrate 300, an element isolation layer 301, an insulator 302, a plug 310, and the like.

The layer L2 includes an insulator 303, a wiring 320, an insulator 304, a plug 311, and the like.

The layer L3 includes an insulator 214, an insulator 216, the transistor OS1, a plug 312, an insulator 282, an insulator 284, a wiring 321, and the like. The first gate of the transistor OS1 functions as the wiring WL, and the second gate of the transistor OS1 functions as the wiring BG.

The layer L4 includes the capacitor C1, a plug 313, the wiring BL, and the like. The capacitor C1 is formed of a conductor 322, a conductor 323, and an insulator 305.

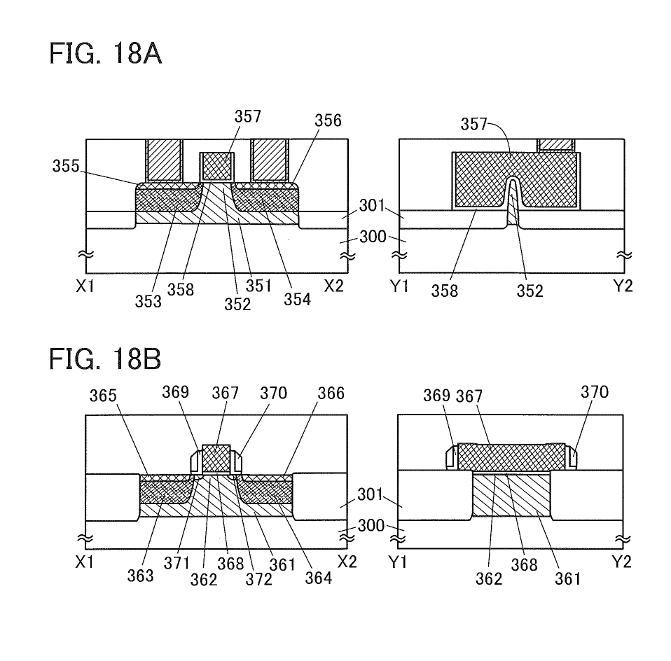

Next, the transistor M1 will be described in detail with reference to FIGS. 18A and 18B. A cross section of the transistor M1 in the channel length direction is shown on the left of FIG. 18A, and a cross section of the transistor M1 in the channel width direction is shown on the right of FIG. 18A.

The transistor M1 is provided on the substrate 300 and isolated from another adjacent transistor by the element isolation layer 301. For the element isolation layer 301, silicon oxide, silicon oxynitride, silicon nitride oxide, silicon nitride, or the like can be used. Note that in this specification, oxynitride refers to a compound that contains more oxygen than nitrogen, and nitride oxide refers to a compound that contains more nitrogen than oxygen.

As the substrate 300, a single crystal semiconductor substrate or a polycrystalline semiconductor substrate of silicon or silicon carbide, a compound semiconductor substrate of silicon germanium, a silicon-on-insulator (SOI) substrate, or the like can be used. Moreover, a glass substrate, a quartz substrate, a plastic substrate, a metal substrate, an attachment film, paper containing a fibrous material, or a base film, for example, may be used as the substrate 300. Alternatively, a semiconductor element may be formed using one substrate and then transferred to another substrate.

Further alternatively, a flexible substrate may be used as the substrate 300. Note that as a method for forming a transistor over a flexible substrate, there is also a method in which a transistor is formed over a non-flexible substrate and then is separated from the non-flexible substrate and transferred to the flexible substrate 300. In that case, a separation layer is preferably provided between the non-flexible substrate and the transistor. As the substrate 300, a sheet, a film, or a foil that contains a fiber may be used. The substrate 300 may have elasticity. The substrate 300 may have a property of returning to its original shape when bending or pulling is stopped; alternatively, the substrate 300 may have a property of not returning to its original shape. The thickness of the substrate 300 ranges, for example, from 5 μm to 700 μm, preferably from 10 μm to 500 μm, further preferably from 15 μm to 300 μm. When the substrate 300 has a small thickness, the weight of a semiconductor device can be reduced. Moreover, when the substrate 300 has a small thickness, even in the case of using glass or the like, the substrate 300 may have elasticity or a property of returning to its original shape after bending or pulling is stopped. Thus, an impact applied to a semiconductor device over the substrate 300, which is caused by dropping or the like, can be reduced. That is, a durable semiconductor device can be provided. When a flexible substrate is used as the substrate 300, a substrate of a metal, an alloy, resin, glass, or fiber thereof can be used, for example. The flexible substrate 300 preferably has a lower coefficient of linear expansion because deformation due to an environment is suppressed. The flexible substrate 300 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon and aramid), polyimide, polycarbonate, acrylic, and polytetrafluoroethylene (PTFE). In particular, aramid is preferably used for the flexible substrate 300 because of its low coefficient of linear expansion.

This embodiment shows an example where a single crystal silicon wafer is used as the substrate 300.

The transistor M1 includes a channel formation region 352 and impurity regions 353 and 354 provided in a well 351, conductive regions 355 and 356 in contact with the impurity regions 353 and 354, a gate insulator 358 over the channel formation region 352, and a gate electrode 357 over the gate insulator 358. Note that the conductive regions 355 and 356 may be formed using metal silicide or the like.

In the transistor M1 in FIG. 18A, the channel formation region 352 has a projecting portion, and the gate insulator 358 and the gate electrode 357 are provided along side and top surfaces of the projecting portion. The transistor with such a shape is referred to as a FIN-type transistor. Although the projecting portion is formed by processing part of the semiconductor substrate in this embodiment, a semiconductor layer with a projecting portion may be formed by processing an SOI substrate.

This embodiment shows an example in which a Si transistor is used as the transistor M1. The transistor M1 may be either an n-channel transistor or a p-channel transistor; a transistor appropriate for an intended circuit is used.

Note that the transistor M1 may be a planar transistor. FIG. 18B shows an example of that case. A cross section of the transistor M1 in the channel length direction is shown on the left of FIG. 18B, and a cross section of the transistor M1 in the channel width direction is shown on the right of FIG. 18B.

The transistor M1 illustrated in FIG. 18B includes a channel formation region 362, low-concentration impurity regions 371 and 372, and high-concentration impurity regions 363 and 364 provided in a well 361; conductive regions 365 and 366 in contact with the high-concentration impurity regions 363 and 364; a gate insulator 368 over the channel formation region 362; a gate electrode 367 over the gate insulator 368; and sidewall insulating layers 369 and 370 provided on sidewalls of the gate electrode 367. Note that the conductive regions 365 and 366 may be formed using metal silicide or the like.

FIG. 16 is described again. The insulator 302 serves as an interlayer insulator. In the case where a Si transistor is used as the transistor M1, the insulator 302 preferably contains hydrogen. When the insulator 302 contains hydrogen, dangling bonds of silicon can be terminated and thus the reliability of the transistor M1 can be improved. For the insulator 302, silicon oxide, silicon oxynitride, silicon nitride oxide, silicon nitride, or the like is preferably used.

The insulator 303 is preferably formed using, for example, a barrier film that prevents hydrogen or impurities from diffusing from the substrate 300, the transistor M1, or the like into a region where the transistor OS1 is formed. For example, silicon nitride formed by a CVD method can be used. Diffusion of hydrogen into an oxide semiconductor contained in the transistor OS1 degrades the characteristics of the oxide semiconductor in some cases. Therefore, a film that prevents hydrogen diffusion is preferably provided between the transistor M1 and the transistor OS1.

The film that prevents hydrogen diffusion means a film from which hydrogen is unlikely to be released. The amount of released hydrogen can be measured by thermal desorption spectroscopy (TDS), for example. The amount of hydrogen released from the insulator 303 that is converted into hydrogen atoms per area of the insulator 303 is less than or equal to 10×10¹⁵ atoms/cm², preferably less than or equal to 5×10¹⁵ atoms/cm² in TDS analysis in the range of 50° C. to 500° C., for example.

For the insulator 304 and the insulator 214, an insulator that inhibits copper diffusion or an insulator with barrier properties against oxygen and hydrogen is preferably used. For a film that inhibits copper diffusion, silicon nitride can be used, for example. Thus, the insulator 304 and the insulator 214 can be formed using a material similar to that used for the insulator 303.

For example, a silicon oxide film or a silicon oxynitride film can be used as the insulator 216.

The insulator 280, the insulator 282, the insulator 284, and the transistor OS1 will be described in detail in Embodiment 5.

The insulator 305 can be formed using, for example, silicon oxide, silicon oxynitride, silicon nitride oxide, silicon nitride, aluminum oxide, aluminum oxynitride, aluminum nitride oxide, aluminum nitride, hafinum oxide, hafnium oxynitride, hafnium nitride oxide, or hafnium nitride.

Alternatively, the insulator 305 may have a stacked-layer structure using any of the above insulators. For example, the insulator 305 may have a stacked-layer structure using a material with high dielectric strength (e.g., silicon oxynitride) and a high dielectric (high-k) material (e.g., aluminum oxide). With this structure, the capacitor C1 can have a sufficient capacitance, and dielectric breakdown can be prevented.

The conductors, wirings, and plugs illustrated in FIG. 16 each preferably have a single-layer structure or a stacked-layer structure of a conductor containing a low-resistance material selected from copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), cobalt (Co), ruthenium (Ru), platinum (Pt), iridium (Ir), and strontium (Sr), an alloy of such a low-resistance material, or a compound containing such a material as its main component. It is particularly preferable to use a high-melting-point material that has both heat resistance and conductivity, such as tungsten or molybdenum. Moreover, it is preferable to use a low-resistance conductive material such as aluminum or copper.

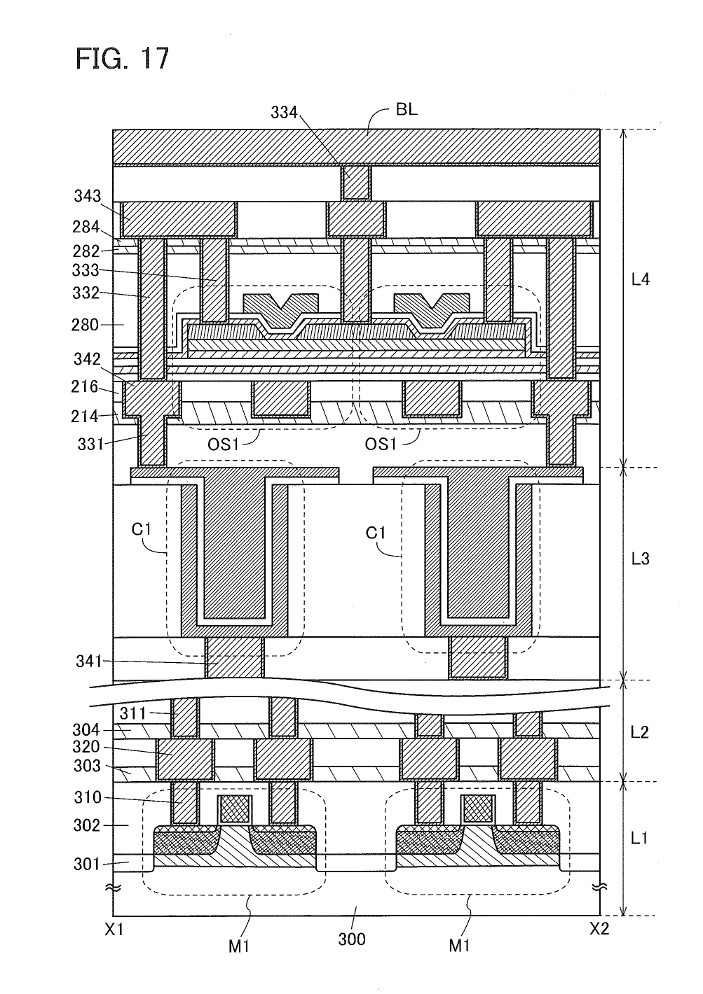

In the MCU 10 of FIG. 16, the transistor OS1 may be formed over the capacitor C1; FIG. 17 shows a cross-sectional view of the MCU 10 with this structure. The cross-sectional view in FIG. 17 is different from that in FIG. 16 in the layer L3 and the layer L4.

In FIG. 17, the layer L3 includes a wiring 341 and the capacitor C1.

In FIG. 17, the layer L4 includes a plug 331, a plug 332, a plug 333, a plug 334, a wiring 342, a wiring 343, the wiring BL, the insulator 214, the insulator 216, the insulator 280, the insulator 282, the insulator 284, and the transistor OS1.

Providing the capacitor C1 below the transistor OS1 can prevent the transistor OS1 from being affected by hydrogen or process damage caused during formation of the capacitor C1.

Although not illustrated in FIG. 16 and FIG. 17, the capacitor C2 is formed in the same layer as the capacitor C1.

In FIG. 16 and FIG. 17, regions without reference numerals or hatch patterns represent regions formed of an insulator. As the insulator, it is possible to use an insulator containing at least one material selected from aluminum oxide, aluminum nitride oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, tantalum oxide, and the like. Alternatively, for these regions, an organic resin such as a polyimide resin, a polyamide resin, an acrylic resin, a siloxane resin, an epoxy resin, or a phenol resin can be used.

### Embodiment 5

In this embodiment, a structure of the OS transistor used in the above embodiments will be described.

### <Oxide Semiconductor>

First, an oxide semiconductor that can be used for the OS transistor will be described.

An oxide semiconductor contains preferably at least indium or zinc, particularly preferably indium and zinc. Here, the case where an oxide semiconductor contains indium, an element M, and zinc is considered.

The element M is preferably gallium (Ga), for example. Other examples of an element that can be used as the element M include aluminum (Al), boron (B), silicon (Si), titanium (Ti), zirconium (Zr), lanthanum (La), cerium (Ce), yttrium (Y), hafnium (Hf), tantalum (Ta), niobium (Nb), and scandium (Sc).

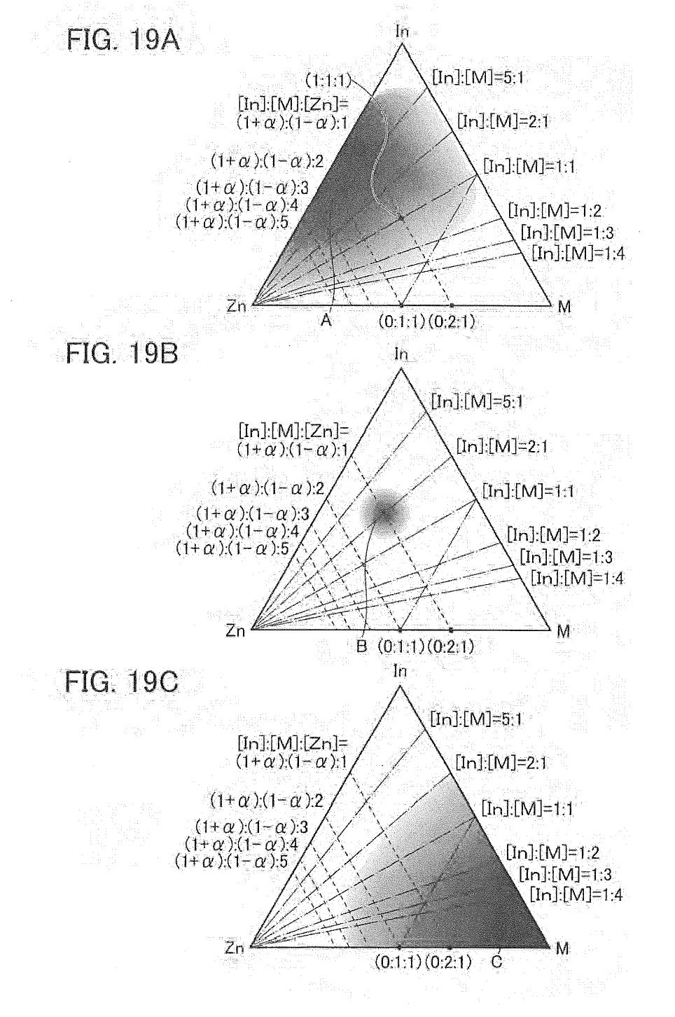

First, preferred ranges of the atomic ratio of indium, the element M, and zinc contained in an oxide semiconductor according to the present invention are described with reference to FIGS. 19A to 19C. Note that the proportion of oxygen atoms is not shown in FIGS. 19A to 19C. Terms of the atomic ratio of indium to the element M and zinc in the oxide semiconductor are denoted by [In], [M], and [Zn].

In FIGS. 19A to 19C, broken lines indicate a line where the atomic ratio [In]:[M]:[Zn] is (1+α):(1−α):1 (where −1≦α≦1), a line where the atomic ratio [In]:[M]:[Zn] is (1+α):(1−α):2, a line where the atomic ratio [In]:[M]:[Zn] is (1+α):(1−α):3, a line where the atomic ratio [In]:[M]:[Zn] is (1+α):(1−α):4, and a line where the atomic ratio [In]:[M]:[Zn] is (1+α):(1−α):5.

Dashed-dotted lines indicate a line where the atomic ratio [In]:[M]:[Zn] is 1:1:3 (where β≧0), a line where the atomic ratio [In]:[M]:[Zn] is 1:2:3, a line where the atomic ratio [In]:[M]:[Zn] is 1:3:β, a line where the atomic ratio [In]:[M]:[Zn] is 1:4:β, a line where the atomic ratio [In]:[M]:[Zn] is 2:1:β, and a line where the atomic ratio [In]:[M]:[Zn] is 5:1:β.

A dashed double-dotted line indicates a line where the atomic ratio [In]:[M]:[Zn] is (1+γ):2:(1−γ), where −1≦γ≦1. An oxide semiconductor with the atomic ratio [In]:[M]:[Zn] of 0:2:1 or around 0:2:1 in FIGS. 19A to 19C tends to have a spinel crystal structure.

A plurality of phases (e.g., two phases or three phases) exist in an oxide semiconductor in some cases. For example, with an atomic ratio [In]:[M]:[Zn] close to 0:2:1, two phases of a spinel crystal structure and a layered crystal structure are likely to exist. In addition, with an atomic ratio [In]:[M]:[Zn] close to 1:0:0, two phases of a bixbyite crystal structure and a layered crystal structure are likely to exist. In the case where a plurality of phases exist in the oxide semiconductor, a grain boundary might be formed between different crystal structures.

In addition, an oxide semiconductor with a higher content of indium can have high carrier mobility (electron mobility). This is because in an oxide semiconductor containing indium, the element M, and zinc, the s orbital of heavy metal mainly contributes to carrier transfer, and a higher indium content in the oxide semiconductor enlarges a region where the s orbitals of indium atoms overlap.

A region A in FIG. 19A represents a region where an oxide semiconductor has high carrier mobility and is likely to have a layered structure with few grain boundaries.

A region B in FIG. 19B represents an atomic ratio [In]:[M]:[Zn] of 4:2:3 to 4:2:4.1 and the vicinity thereof. The vicinity includes an atomic ratio [In]:[M]:[Zn] of 5:3:4. An oxide semiconductor with an atomic ratio represented by the region B is an excellent oxide semiconductor that has particularly high crystallinity and high carrier mobility.

In contrast, when the indium content and the zinc content in an oxide semiconductor become lower, the carrier mobility becomes lower. Thus, with an atomic ratio [In]:[M]:[Zn] of 0:1:0 or around 0:1:0 (e.g., a region C in FIG. 19C), insulation performance becomes better.

### <Transistor Structure 1>

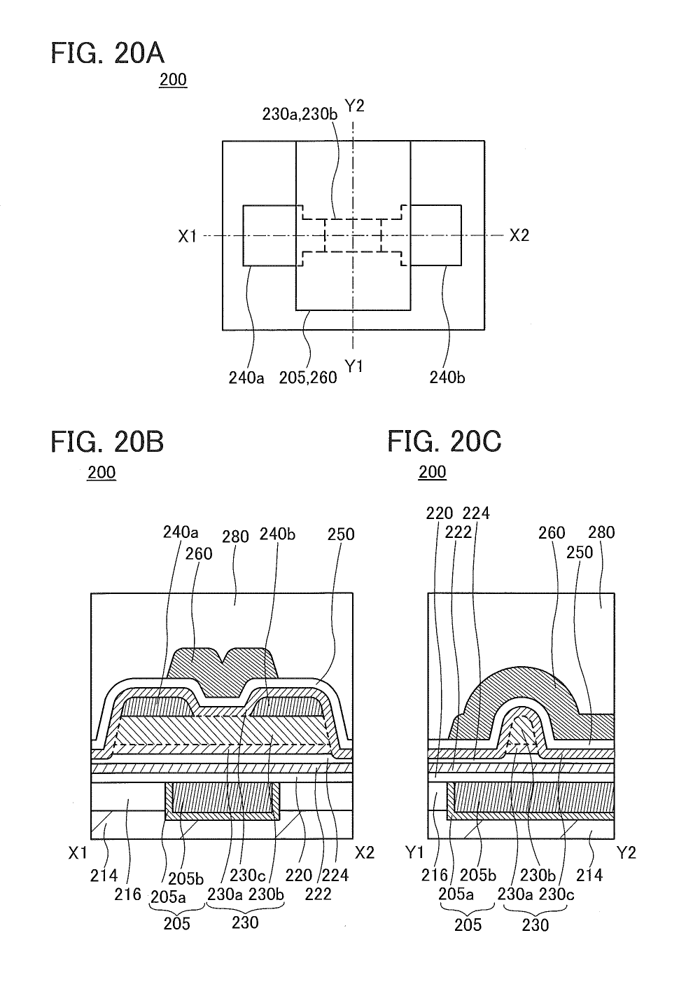

FIGS. 20A to 20C are a top view and cross-sectional views of a transistor 200. FIG. 20A is the top view. FIG. 20B is a cross-sectional view along the dashed-dotted line X1-X2 in FIG. 20A. FIG. 20C is a cross-sectional view along the dashed-dotted line Y1-Y2 in FIG. 20A. Note that some components are not illustrated in the top view of FIG. 20A for simplification of the drawing.

FIGS. 20B and 20C illustrate an example in which the transistor 200 is provided over the insulator 214 and the insulator 216.

The transistor 200 includes a conductor 205 (conductors 205a and 205b) and a conductor 260 that function as gate electrodes, insulators 220, 222, 224, and 250 that function as gate insulating layers, an oxide semiconductor 230 (oxide semiconductors 230a, 230b, and 230c), a conductor 240a that functions as one of a source and a drain, a conductor 240b that functions as the other of the source and the drain, and an insulator 280 that contains excess oxygen (contains oxygen in excess of that in the stoichiometric composition).

In the transistor 200, the conductor 260 is referred to as a top gate and the conductor 205 is referred to as a bottom gate in some cases. Alternatively, the conductor 260 is referred to as a front gate and the conductor 205 is referred to as a back gate in some cases.

The oxide semiconductor 230 includes the oxide semiconductor 230a, the oxide semiconductor 230b over the oxide semiconductor 230a, and the oxide semiconductor 230c over the oxide semiconductor 230b. When the transistor 200 is turned on, a current flows mainly in the oxide semiconductor 230b. That is, the oxide semiconductor 230b functions as a channel formation region. Meanwhile, although a current sometimes flows through a region in the vicinity of the interface (a mixed region in some cases) between the oxide semiconductor 230b and the oxide semiconductors 230a and 230c, the other regions of the oxide semiconductors 230a and 230c sometimes function as insulators.

The conductor 205 is formed using a metal film containing an element selected from molybdenum, titanium, tantalum, tungsten, aluminum, copper, chromium, neodymium, and scandium; a metal nitride film containing any of the above elements as its component (e.g., a titanium nitride film, a molybdenum nitride film, or a tungsten nitride film); or the like. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

For example, it is preferable to use a conductor with a barrier property against hydrogen (e.g., tantalum nitride) as the conductor 205a and stack tungsten, which has high conductivity, as the conductor 205b over the conductor 205a. The use of the combination of such materials can prevent diffusion of hydrogen into the oxide semiconductor 230 while conductivity of a wiring is ensured. A two-layer structure of the conductor 205a and the conductor 205b is shown in FIGS. 20A to 20C; however, the structure of the conductor 205 is not limited thereto and may employ a single-layer structure or a stacked-layer structure of three or more layers.

Each of the insulators 220 and 224 is preferably an insulator containing oxygen, such as a silicon oxide film or a silicon oxynitride film. In particular, the insulator 224 is preferably an insulator containing excess oxygen. When such an insulator containing excess oxygen is provided in contact with the oxide semiconductor in the transistor 200, oxygen vacancies in the oxide semiconductor can be compensated. Note that the insulator 220 and the insulator 224 are not necessarily formed of the same material.

The insulator 222 preferably has a single-layer structure or a stacked-layer structure using an insulator containing a high-k material such as silicon nitride oxide, aluminum oxide, hafnium oxide, tantalum oxide, zirconium oxide, lead zirconate titanate (PZT), strontium titanate (SrTiO₃), or (Ba,Sr)TiO₃ (BST), for example. Aluminum oxide, bismuth oxide, germanium oxide, niobium oxide, silicon oxide, titanium oxide, tungsten oxide, yttrium oxide, or zirconium oxide may be added to the insulator, for example. The insulator may be subjected to nitriding treatment. A layer of silicon oxide, silicon oxynitride, or silicon nitride may be stacked over the insulator.

Note that the insulator 222 may have a stacked-layer structure of two or more layers. In this case, the stacked layers are not necessarily formed of the same material but may be formed of different materials.

In the case where the insulator 222 containing a high-k material is provided between the insulator 220 and the insulator 224, the insulator 222 can be negatively charged. That is, the insulator 222 can function as a charge accumulation layer.

For example, in the case where the insulator 220 and the insulator 224 are formed using silicon oxide and the insulator 222 is formed using a material having a lot of electron trap states (e.g., hafnium oxide, aluminum oxide, or tantalum oxide), the state where the potential of the conductor 205 is higher than the potential of the source electrode and the drain electrode is kept at a temperature higher than the operating temperature or the storage temperature of a semiconductor device (e.g., at a temperature ranging from 125° C. to 450° C., typically from 150° C. to 300° C.) for 10 milliseconds or longer, typically one minute or longer. Thus, electrons are moved from the oxide semiconductor in the transistor 200 to the conductor 205. At this time, some of the moving electrons are trapped by the electron trap states of the insulator 222.

In the transistor in which a necessary amount of electrons is trapped by the electron trap states of the insulator 222, Vₜₕ is shifted in the positive direction. By controlling the voltage of the conductor 205, the amount of electrons to be trapped can be controlled, and thus Vₜₕ can be controlled.

The treatment for trapping the electrons can be performed in the manufacturing process of the transistor. For example, the treatment can be performed at any step before factory shipment, such as after the formation of a conductor connected to a source electrode or a drain electrode of the transistor, after the wafer process, after a wafer-dicing step, or after packaging.

Appropriate adjustment of the thicknesses of the insulator 220, the insulator 222, and the insulator 224 can control Vₜₕ or provide a transistor with a low leakage current in an off state. The insulator 220, the insulator 222, and the insulator 224 are preferably thin, in which case, Vₜₕ can be easily controlled by the conductor 205. For example, each of the insulator 220, the insulator 222, and the insulator 224 has a thickness of preferably 50 nm or less, further preferably 30 nm or less, still further preferably 10 nm or less, still further preferably 5 nm or less.

The oxide semiconductor 230a, the oxide semiconductor 230b, and the oxide semiconductor 230c are formed using metal oxide such as In-M-Zn oxide. The oxide semiconductor 230 may be formed using In—Ga oxide or In—Zn oxide.

The energy level of the conduction band minimum of each of the oxide semiconductors 230a and 230c is closer to the vacuum level than that of the oxide semiconductor 230b. Typically, a difference in the energy level between the conduction band minimum of the oxide semiconductor 230b and the conduction band minimum of each of the oxide semiconductors 230a and 230c is preferably greater than or equal to 0.15 eV or greater than or equal to 0.5 eV, and less than or equal to 2 eV or less than or equal to 1 eV. That is, a difference in the electron affinity between the oxide semiconductor 230b and each of the oxide semiconductors 230a and 230c is preferably greater than or equal to 0.15 eV or greater than or equal to 0.5 eV, and less than or equal to 2 eV or less than or equal to 1 eV.

The energy gap of the oxide semiconductor 230b is preferably 2 eV or more, further preferably 2.5 eV or more and 3.0 eV or less. The energy gap of each of the oxide semiconductors 230a and 230c is preferably 2 eV or more, further preferably 2.5 eV or more, still further preferably 2.7 eV or more and 3.5 eV or less. The energy gap of each of the oxide semiconductors 230a and 230c is preferably greater than that of the oxide semiconductor 230b. For example, a difference in the energy gap between the oxide semiconductors 230a and 230b is preferably 0.15 eV or more, 0.5 eV or more, 1.0 eV or more and 2 eV or less or 1 eV or less. Similarly, a difference in the energy gap between the oxide semiconductors 230c and 230b is preferably 0.15 eV or more, 0.5 eV or more, 1.0 eV or more and 2 eV or less or 1 eV or less.

The thickness of each of the oxide semiconductors 230a, 230b, and 230c is greater than or equal to 3 nm and less than or equal to 200 nm, preferably greater than or equal to 3 nm and less than or equal to 100 nm, further preferably greater than or equal to 3 nm and less than or equal to 60 nm.

A decrease in the carrier density of an oxide semiconductor is preferable, in which case the negative shift of the threshold voltage of the transistor can be inhibited or the off-state current of the transistor can be reduced.

Examples of a factor affecting the carrier density of an oxide semiconductor include oxygen vacancy (Vo) and impurities in the oxide semiconductor. As the amount of oxygen vacancy in the oxide semiconductor increases, the density of defect states increases when hydrogen is bonded to the oxygen vacancy (this state is also referred to as VoH). The density of defect states also increases with an increase in the amount of impurities in the oxide semiconductor. Hence, the carrier density of an oxide semiconductor can be controlled by controlling the density of defect states in the oxide semiconductor.

A state with a low impurity concentration and a low density of defect states is referred to as a highly purified intrinsic or substantially highly purified intrinsic state. A highly purified intrinsic or substantially highly purified intrinsic oxide semiconductor has few carrier generation sources, and thus can have a low carrier density.

A highly purified intrinsic or substantially highly purified intrinsic oxide semiconductor is preferably used as each of the oxide semiconductors 230a and 230c. For example, the carrier density of each of the oxide semiconductors 230a and 230c is lower than 8×10¹⁵ cm⁻³, preferably lower than 1×10¹¹ cm⁻³, further preferably lower than 1×10¹⁰ cm⁻³ and higher than or equal to 1×10⁻⁹ cm⁻³.

In contrast, the carrier density of an oxide semiconductor is preferably increased in order to improve the on-state current or field-effect mobility of a transistor. In order to increase the carrier density of the oxide semiconductor, the impurity concentration or the density of defect states in the oxide semiconductor is slightly increased, or alternatively, the bandgap of the oxide semiconductor is narrowed. For example, an oxide semiconductor that has a slightly high impurity concentration or a slightly high density of defect states in the range where a favorable on/off ratio is obtained in the I_{D}-V_{G} characteristics of the transistor can be regarded as substantially intrinsic. Furthermore, an oxide semiconductor that has a narrow bandgap so as to increase the density of thermally excited electrons (carriers) can be regarded as substantially intrinsic. Note that a transistor using an oxide semiconductor with higher electron affinity has lower threshold voltage.

The aforementioned oxide semiconductor with an increased carrier density has somewhat n-type conductivity, and thus can be referred to as a “slightly-n” oxide semiconductor.

The carrier density of the oxide semiconductor 230b is preferably higher than those of the oxide semiconductor 230a and the oxide semiconductor 230c. The carrier density of the oxide semiconductor 230b is preferably higher than or equal to 1×10⁵ cm⁻³ and lower than 1×10¹⁸ cm⁻³, further preferably higher than or equal to 1×10⁷ cm⁻³ and lower than or equal to 1×10¹⁷ cm⁻³, still further preferably higher than or equal to 1×10⁹ cm⁻³ and lower than or equal to 5×10¹⁶ cm⁻³, yet further preferably higher than or equal to 1×10¹⁰ cm⁻³ and lower than or equal to 1×10¹⁶ cm⁻³, and yet still preferably higher than or equal to 1×10¹¹ cm⁻³ and lower than or equal to 1×10¹⁵ cm⁻³.

The density of defect states in a mixed layer formed at an interface between the oxide semiconductors 230a and 230b or an interface between the oxide semiconductors 230b and 230c is preferably made low.

Specifically, when the oxide semiconductors 230a and 230b or the oxide semiconductors 230b and 230c contain the same element (as a main component) in addition to oxygen, a mixed layer with a low density of defect states can be formed. For example, in the case where the oxide semiconductor 230b is an In—Ga—Zn oxide semiconductor, it is preferable to use an In—Ga—Zn oxide semiconductor, a Ga—Zn oxide semiconductor, gallium oxide, or the like as each of the oxide semiconductors 230a and 230c.

At this time, the oxide semiconductor 230b serves as a main carrier path. Since the density of defect states at the interface between the oxide semiconductors 230a and 230b and the interface between the oxide semiconductors 230b and 230c can be made low, the influence of interface scattering on carrier conduction is small, and a high on-state current can be obtained.

When an electron is trapped in a trap state, the trapped electron behaves like fixed charge; thus, Vₜₕ of the transistor is shifted in the positive direction. The oxide semiconductors 230a and 230c can make the trap state apart from the oxide semiconductor 230b. This structure can prevent the positive shift of Vₜₕ of the transistor.

A material whose conductivity is sufficiently lower than that of the oxide semiconductor 230b is used for the oxide semiconductors 230a and 230c. In that case, the oxide semiconductor 230b, the interface between the oxide semiconductors 230a and 230b, and the interface between the oxide semiconductors 230b and 230c mainly function as a channel region. For example, an oxide semiconductor with high insulation performance and the atomic ratio represented by the region C in FIG. 19C can be used as the oxide semiconductors 230a and 230c. Note that the region C in FIG. 19C shows the atomic ratio [In]:[M]:[Zn] of 0:1:0 or around 0:1:0.

In the case where an oxide semiconductor with the atomic ratio represented by the region A in FIG. 19A is used as the oxide semiconductor 230b, it is particularly preferable to use an oxide semiconductor with [M]/[In] of greater than or equal to 1, preferably greater than or equal to 2, as each of the oxide semiconductors 230a and 230c. In addition, it is suitable to use an oxide semiconductor with [M]/([Zn]±[In]) of greater than or equal to 1 and sufficiently high insulation performance as the oxide semiconductor 230c.

The oxide semiconductor 230c has lower crystallinity than the oxide semiconductor 230b in some cases. The oxide semiconductor 230b preferably contains a c-axis-aligned crystalline oxide semiconductor (CAAC-OS) that will be described later. The reduction in crystallinity of the oxide semiconductor 230c sometimes makes the oxide semiconductor 230c have a higher oxygen-transmitting property, leading to easy supply of oxygen from the insulator positioned above the oxide semiconductor 230c to the oxide semiconductor 230b. Here, the oxide semiconductor 230c may be an amorphous semiconductor or amorphous-like (a-like) OS described later.

The oxide semiconductor 230a may contain a CAAC-OS. Furthermore, the oxide semiconductor 230a preferably has higher crystallinity than the oxide semiconductor 230c.

Like the insulator 224, the insulator 250 is preferably an oxide insulator that contains oxygen in excess of the stoichiometric composition. When such an insulator containing excess oxygen is provided in contact with the oxide semiconductor 230, oxygen vacancies in the oxide semiconductor 230 can be reduced.

As the insulator 250, it is possible to use an insulating film with barrier properties against oxygen and hydrogen, such as a film formed of aluminum oxide, aluminum oxynitride, hafnium oxide, hafnium oxynitride, or silicon nitride. The insulator formed of such a material functions as a layer that prevents release of oxygen from the oxide semiconductor 230 or entry of impurities such as hydrogen from the outside.

Note that the insulator 250 may have a stacked-layer structure similar to that of the insulator 220, the insulator 222, and the insulator 224. When the insulator 250 includes an insulator in which a necessary amount of electrons is trapped by electron trap states, Vₜₕ of the transistor 200 can be shifted in the positive direction. The transistor 200 having the structure is a normally-off transistor that is in a non-conduction state (also referred to as off state) even when the gate voltage is 0 V.

In addition to the insulator 250, a barrier film may be provided between the oxide semiconductor 230 and the conductor 260. Alternatively, the oxide semiconductor 230c may have a barrier property.

For example, an insulating film containing excess oxygen is provided in contact with the oxide semiconductor 230 and covered by a barrier film, whereby the composition of the oxide semiconductor can be almost the same as the stoichiometric composition or can be in a supersaturated state containing more oxygen than that in the stoichiometric composition. It is also possible to prevent entry of impurities such as hydrogen into the oxide semiconductor 230.

One of the conductor 240a and the conductor 240b functions as a source electrode, and the other functions as a drain electrode.

A metal such as aluminum, titanium, chromium, nickel, copper, yttrium, zirconium, molybdenum, silver, tantalum, or tungsten or an alloy containing any of the metals as its main component can be used for the conductors 240a and 240b. Although a single layer structure is shown, a stacked-layer structure of two or more layers may be employed.

For example, each of the conductors 240a and 240b can have a stacked-layer structure of a titanium film and an aluminum film. Other examples include a two-layer structure where an aluminum film is stacked over a tungsten film, a two-layer structure where a copper film is stacked over a copper-magnesium-aluminum alloy film, a two-layer structure where a copper film is stacked over a titanium film, and a two-layer structure where a copper film is stacked over a tungsten film.

Other examples include a three-layer structure where a titanium film or a titanium nitride film, an aluminum film or a copper film, and a titanium film or a titanium nitride film are stacked in this order; and a three-layer structure where a molybdenum film or a molybdenum nitride film, an aluminum film or a copper film, and a molybdenum film or a molybdenum nitride film are stacked in this order. Note that a transparent conductive material containing indium oxide, tin oxide, or zinc oxide may be used.

The conductor 260 functioning as a gate electrode can be formed using, for example, a metal selected from aluminum, chromium, copper, tantalum, titanium, molybdenum, and tungsten, an alloy containing any of these metals as its component, or an alloy containing any of these metals in combination. Furthermore, one or both of manganese and zirconium may be used. Alternatively, a semiconductor typified by polycrystalline silicon doped with an impurity element such as phosphorus, or silicide such as nickel silicide may be used.

For example, the conductor 260 can have a two-layer structure in which a titanium film is stacked over an aluminum film. Other examples include a two-layer structure where a titanium film is stacked over a titanium nitride film, a two-layer structure where a tungsten film is stacked over a titanium nitride film, and a two-layer structure where a tungsten film is stacked over a tantalum nitride film or a tungsten nitride film.

Another example is a three-layer structure where a titanium film, an aluminum film, and a titanium film are stacked in this order. Alternatively, an alloy film or a nitride film that contains aluminum and one or more elements selected from titanium, tantalum, tungsten, molybdenum, chromium, neodymium, and scandium may be used.

The conductor 260 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. The conductor 260 can have a stacked-layer structure using the above light-transmitting conductive material and the above metal.

By using a material with a high work function for the conductor 260, Vₜₕ of the transistor 200 can be increased and the cutoff current can be lowered. A conductive material whose work function is preferably 4.8 eV or more, further preferably 5.0 eV or more, still further preferably 5.2 eV or more, still further preferably 5.4 eV or more, yet still further preferably 5.6 eV or more is used for the conductor 260. Examples of a conductive material with a high work function include molybdenum, molybdenum oxide, Pt, Pt silicide, Ni silicide, indium tin oxide, and In—Ga—Zn oxide to which nitrogen is added.

The insulator 280 is provided over the transistor 200. The insulator 280 preferably contains excess oxygen. In particular, when an insulator containing excess oxygen is provided as an interlayer film or the like in the vicinity of the transistor 200, oxygen vacancies in the transistor 200 are reduced, whereby the reliability can be improved.

As the insulator containing excess oxygen, specifically, an oxide material that releases part of oxygen by heating is preferably used. An oxide material that releases part of oxygen by heating is an oxide film of which the amount of released oxygen converted into oxygen atoms is greater than or equal to 1.0×10¹⁸ atoms/cm³, preferably greater than or equal to 3.0×10²⁰ atoms/cm³ in TDS analysis. Note that the temperature of the film surface in the TDS analysis is preferably higher than or equal to 100° C. and lower than or equal to 700° C., or higher than or equal to 100° C. and lower than or equal to 500° C.

As such a material, a material containing silicon oxide or silicon oxynitride is preferably used, for example. Alternatively, metal oxide can be used. Note that in this specification, silicon oxynitride refers to a material that contains oxygen at a higher proportion than nitrogen, and silicon nitride oxide refers to a material that contains nitrogen at a higher proportion than oxygen.

The insulator 280 covering the transistor 200 may function as a planarization film that covers roughness thereunder.

### <Transistor Structure 2>

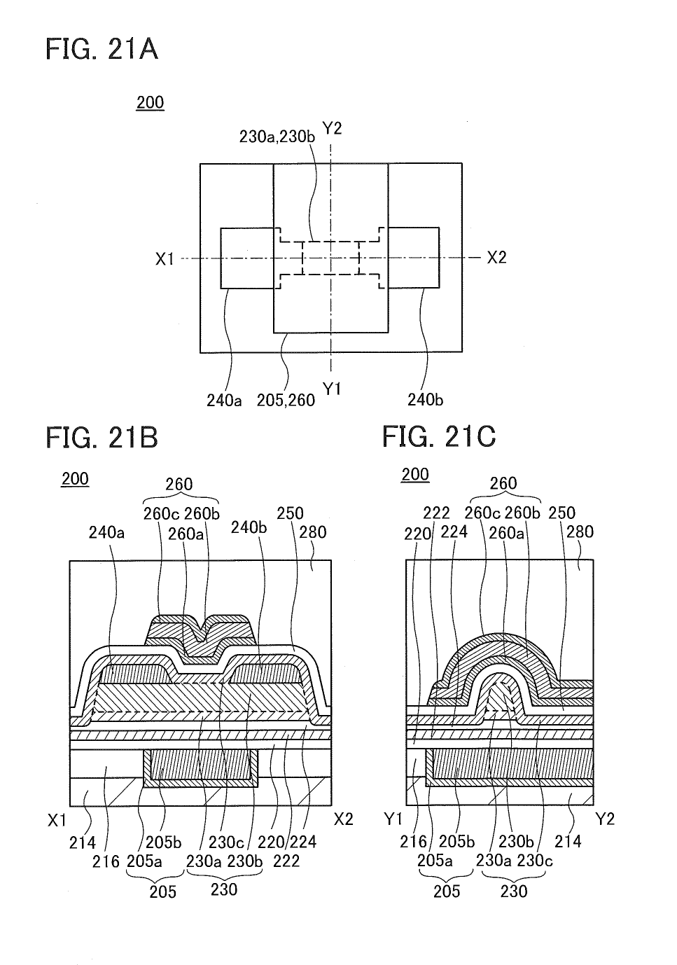

FIGS. 21A to 21C illustrate an example of a structure that can be used for the transistor 200. FIG. 21A illustrates a top surface of the transistor 200. Some films are omitted in FIG. 21A for simplification of the drawing. FIG. 21B is a cross-sectional view along the dashed-dotted line X1-X2 in FIG. 21A. FIG. 21C is a cross-sectional view along the dashed-dotted line Y1-Y2 in FIG. 21A.

Note that in the transistor 200 in FIGS. 21A to 21C, components having the same function as those in the transistor 200 in FIGS. 20A to 20C are denoted by the same reference numerals.

In the structure illustrated in FIGS. 21A to 21C, the conductor 260 functioning as the gate electrode includes a conductor 260a, a conductor 260b, and a conductor 260c.

The conductor 260a is formed by a thermal CVD method, an MOCVD method, or an atomic layer deposition (ALD) method, and preferably by an ALD method. By employing an ALD method or the like, plasma damage to the insulator 250 can be reduced. Furthermore, it is preferable to form the conductor 260a by an ALD method or the like because coverage can be improved. Thus, the transistor 200 with high reliability can be provided.

The conductor 260b is formed using a material having high conductivity, such as tantalum, tungsten, copper, or aluminum. The conductor 260c formed over the conductor 260b is preferably formed using a conductor that is hardly oxidized, such as tungsten nitride. In the case where the insulator 280 is formed using an oxide material from which oxygen is released, the conductor 260 can be prevented from being oxidized by the released oxygen.

Thus, oxidation of the conductor 260 can be prevented, and oxygen released from the insulator 280 can be supplied to the oxide semiconductor 230 efficiently.

A conductor that is not easily oxidized is used for the conductor 260c having a large contact area with the insulator 280 containing excess oxygen, whereby excess oxygen in the insulator 280 can be prevented from being absorbed into the conductor 260. Furthermore, the use of a conductor with high conductivity for the conductor 260b can provide the transistor 200 with low power consumption.

### <Transistor Structure 3>

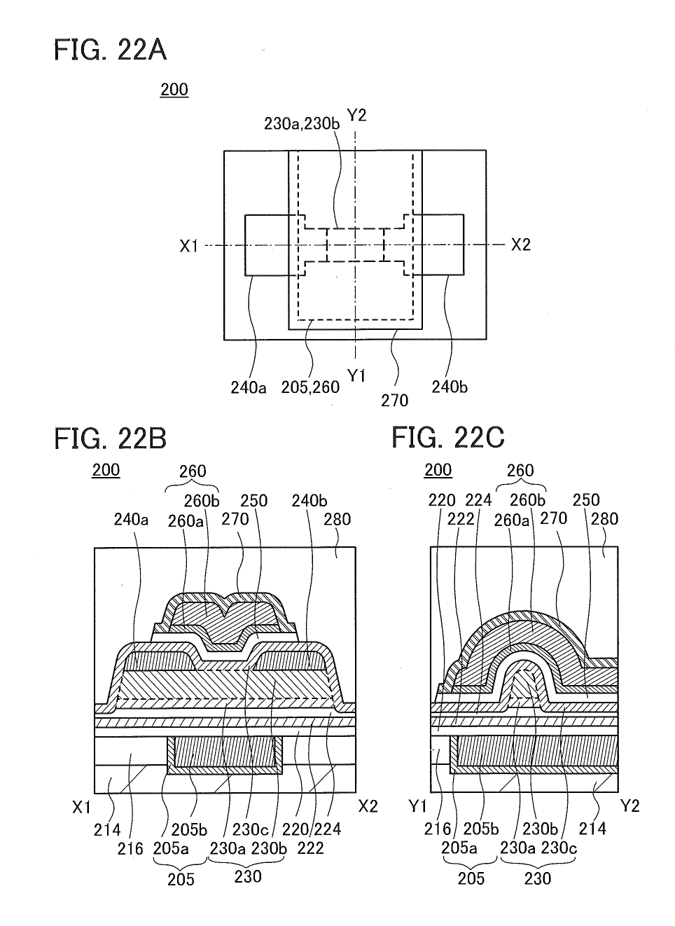

FIGS. 22A to 22C illustrate an example of a structure that can be used for the transistor 200. FIG. 22A illustrates a top surface of the transistor 200. Some films are omitted in FIG. 22A for simplification of the drawing. FIG. 22B is a cross-sectional view along the dashed-dotted line X1-X2 in FIG. 22A. FIG. 22C is a cross-sectional view along the dashed-dotted line Y1-Y2 in FIG. 22A.

Note that in the transistor 200 in FIGS. 22A to 22C, components having the same function as those in the transistor 200 in FIGS. 20A to 20C are denoted by the same reference numerals.

In the structure shown in FIGS. 22A to 22C, the conductor 260 functioning as the gate electrode has a stacked-layer structure of the conductors 260a and 260b. Furthermore, an insulator 270 is formed over the conductor 260 functioning as the gate electrode.

The conductor 260a is formed by a thermal CVD method, an MOCVD method, or an ALD method, and preferably by an ALD method. By employing an ALD method or the like, plasma damage to the insulator 250 can be reduced. Furthermore, it is preferable to form the conductor 260a by an ALD method or the like because coverage can be improved. Thus, the transistor 200 with high reliability can be provided.

The conductor 260b is formed using a material with high conductivity, such as tantalum, tungsten, copper, or aluminum.

The insulator 270 is provided to cover the conductor 260. In the case where the insulator 280 is formed using an oxide material from which oxygen is released, the insulator 270 is formed using a substance with a barrier property against oxygen to prevent the conductor 260 from being oxidized by the released oxygen.

For example, the insulator 270 can be formed using metal oxide such as aluminum oxide. The insulator 270 is formed to a thickness with which oxidation of the conductor 260 is prevented. For example, the thickness of the insulator 270 is set greater than or equal to 1 nm and less than or equal to 10 nm, preferably greater than or equal to 3 nm and less than or equal to 7 nm.

Thus, oxidation of the conductor 260 can be prevented, and oxygen released from the insulator 280 can be supplied to the oxide semiconductor 230 efficiently.

### <Transistor Structure 4>

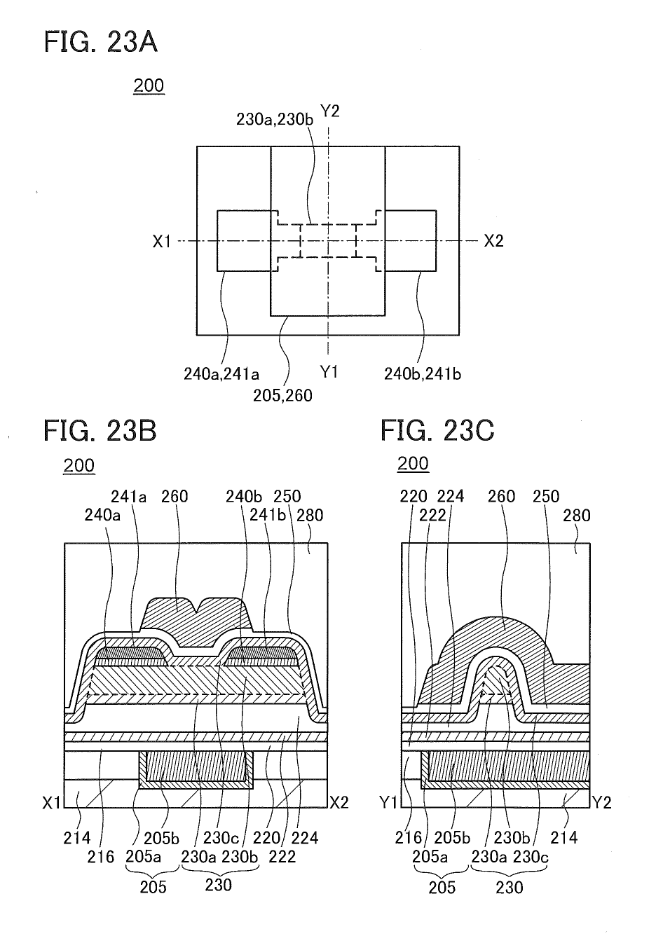

FIGS. 23A to 23C illustrate an example of a structure that can be used for the transistor 200. FIG. 23A illustrates a top surface of the transistor 200. Some films are omitted in FIG. 23A for simplification of the drawing. FIG. 23B is a cross-sectional view along the dashed-dotted line X1-X2 in FIG. 23A. FIG. 23C is a cross-sectional view along the dashed-dotted line Y1-Y2 in FIG. 23A.

Note that in the transistor 200 in FIGS. 23A to 23C, components having the same function as those in the transistor 200 in FIGS. 20A to 20C are denoted by the same reference numerals.

In the structure shown in FIGS. 23A to 23C, conductors serving as a source and a drain have a stacked-layer structure. It is preferable to use conductors having high adhesion to the oxide semiconductor 230b as the conductors 240a and 240b, and use conductors having high conductivity as the conductors 241a and 241b. The conductors 240a and 240b are preferably formed by an ALD method. It is preferable to use an ALD method or the like because coverage can be improved.

For example, when metal oxide containing indium is used for the oxide semiconductor 230b, titanium nitride or the like is used for the conductors 240a and 240b. Furthermore, when the conductors 241a and 241b are formed using a material having high conductivity, such as tantalum, tungsten, copper, or aluminum, the transistor 200 with high reliability and low power consumption can be provided.

As illustrated in FIG. 23C, in the channel width direction of the transistor 200, the oxide semiconductor 230b is covered with the conductor 260, and the insulator 224 has a projecting portion. By adjusting the shape of the projecting portion of the insulator 224, a bottom surface of the conductor 260 can be made closer to the substrate than a bottom surface of the oxide semiconductor 230b. That is, the transistor 200 has a structure in which the oxide semiconductor 230b can be electrically surrounded by electric fields of the conductors 205 and 260. Such a structure in which the oxide semiconductor 230b is electrically surrounded by electric fields of the conductors is referred to as a surrounded channel (s-channel) structure. In the transistor 200 with the s-channel structure, a channel can be formed in the whole (bulk) of the oxide semiconductor 230b. The s-channel structure can increase the drain current of the transistor and increase the on-state current (current that flows between the source and the drain when the transistor is on). Furthermore, the entire channel formation region of the oxide semiconductor 230b can be depleted by electric fields of the conductors 205 and 260. Accordingly, the off-state current of the s-channel transistor can be further reduced. When the channel width is shortened, the advantageous effects of the s-channel structure, such as an increase in on-state current and a reduction in off-state current, can be enhanced.

### <Transistor Structure 5>

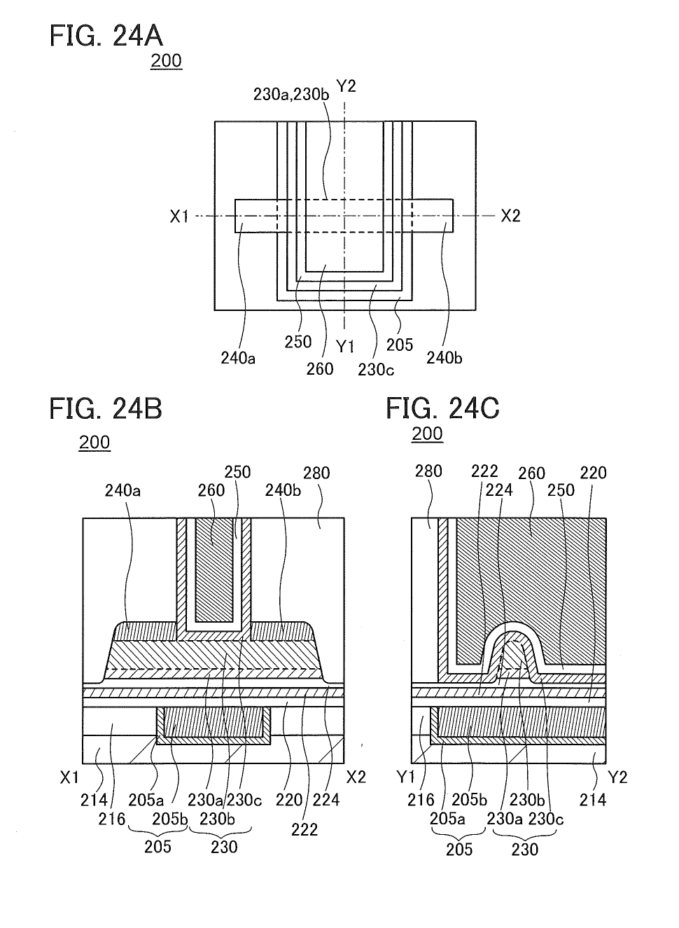

FIGS. 24A to 24C illustrate an example of a structure that can be used for the transistor 200. FIG. 24A illustrates a top surface of the transistor 200. Some films are omitted in FIG. 24A for simplification of the drawing. FIG. 24B is a cross-sectional view along the dashed-dotted line X1-X2 in FIG. 24A. FIG. 24C is a cross-sectional view along the dashed-dotted line Y1-Y2 in FIG. 24A.

Note that in the transistor 200 in FIGS. 24A to 24C, components having the same function as those in the transistor 200 in FIGS. 20A to 20C are denoted by the same reference numerals.

The oxide semiconductor 230c, the insulator 250, and the conductor 260 are formed in an opening formed in the insulator 280.

Since the transistor 200 illustrated in FIGS. 24A to 24C has a structure in which the conductor 260 hardly overlaps the conductors 240a and 240b, the parasitic capacitance added to the conductor 260 can be reduced. Thus, the transistor 200 with high operating frequency can be provided.

### <Transistor Structure 6>

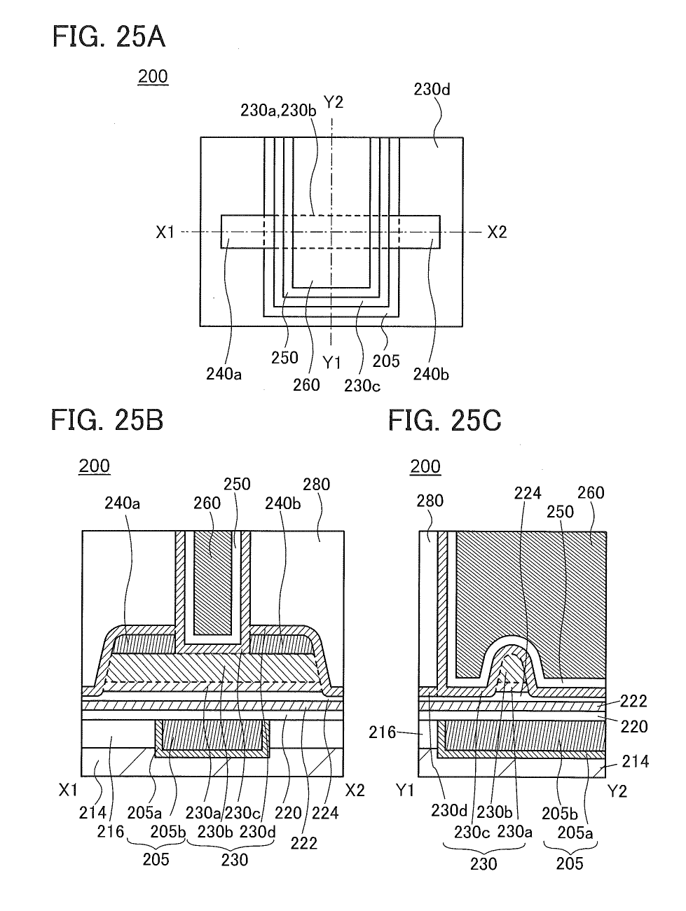

FIGS. 25A to 25C illustrate an example of a structure that can be used for the transistor 200. FIG. 25A illustrates a top surface of the transistor 200. Some films are omitted in FIG. 25A for simplification of the drawing. FIG. 25B is a cross-sectional view along the dashed-dotted line X1-X2 in FIG. 25A. FIG. 25C is a cross-sectional view along the dashed-dotted line Y1-Y2 in FIG. 25A.

Note that in the transistor 200 in FIGS. 25A to 25C, components having the same function as those in the transistor 200 in FIGS. 20A to 20C are denoted by the same reference numerals.

In the transistor 200 illustrated in FIGS. 25A to 25C, the oxide semiconductor 230c, the insulator 250, and the conductor 260 are formed in an opening formed in the insulator 280.

Since the transistor 200 illustrated in FIGS. 25A to 25C has a structure in which the conductor 260 hardly overlaps the conductors 240a and 240b, the parasitic capacitance added to the conductor 260 can be reduced. In other words, the transistor 200 with high operating frequency can be provided.

The oxide semiconductor 230d is provided between the oxide semiconductor 230b and the insulator 280 containing excess oxygen. Therefore, generation of a shallow level in the vicinity of the channel formed in the oxide semiconductor 230b is inhibited more than in the case where the oxide semiconductor 230b is directly in contact with the insulator 280 as in FIGS. 24A to 24C. Thus, a semiconductor device with high reliability can be provided.

### Embodiment 6

In this embodiment, a structure of an oxide semiconductor that can be used for the OS transistor will be described.

In this specification, the term “parallel” indicates that the angle formed between two straight lines ranges from −10° to 10°, and accordingly also includes the case where the angle ranges from −5° to 5°. The term “substantially parallel” indicates that the angle formed between two straight lines ranges from −30° to 30°. The term “perpendicular” indicates that the angle formed between two straight lines ranges from 80° to 100°, and accordingly also includes the case where the angle ranges from 85° to 95°. The term “substantially perpendicular” indicates that the angle formed between two straight lines ranges from 60° to 120°.

In this specification, trigonal and rhombohedral crystal systems are included in a hexagonal crystal system.

### <Structure of Oxide Semiconductor>

The structure of an oxide semiconductor will be described below.

An oxide semiconductor is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

An amorphous structure is generally thought to be isotropic and have no non-uniform structure, to be metastable and not to have fixed positions of atoms, to have a flexible bond angle, and to have a short-range order but have no long-range order, for example.

This means that a stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. In contrast, an a-like OS, which is not isotropic, has an unstable structure that contains a void. Because of its instability, an a-like OS is close to an amorphous oxide semiconductor in terms of physical properties.

### <CAAC-OS>

First, a CAAC-OS will be described.

A CAAC-OS is an oxide semiconductor having a plurality of c-axis-aligned crystal parts (also referred to as pellets).

Analysis of a CAAC-OS by X-ray diffraction (XRD) is described. For example, when the structure of a CAAC-OS including an InGaZnO₄ crystal that is classified into the space group R-3m is analyzed by an out-of-plane method, a peak appears at a diffraction angle (2θ) of around 31°. This peak is derived from the (009) plane of the InGaZnO₄ crystal, which indicates that crystals in the CAAC-OS have c-axis alignment, and that the c-axes are aligned in a direction substantially perpendicular to a surface where the CAAC-OS film is formed (also referred to as formation surface) or the top surface of the CAAC-OS film. Note that a peak sometimes appears at a 2θ of around 36° in addition to the peak at a 2θ of around 31°. The peak at a 2θ of around 36° is derived from a crystal structure classified into the space group Fd-3m. Therefore, it is preferred that the CAAC-OS do not show the peak at a 2θ of around 36°.

Furthermore, in structural analysis of the CAAC-OS by an in-plane method in which an X-ray is incident on the CAAC-OS in a direction parallel to the formation surface, a peak appears at a 2θ of around 56°. This peak is derived from the (110) plane of the InGaZnO₄ crystal. When analysis (φ scan) is performed with a 2θ fixed at around 56° and with the sample rotated using a normal vector of the sample surface as an axis (φ axis), no clear peak appears. Meanwhile, when single crystal InGaZnO₄ is subjected to φ scan with a 2θ fixed at around 56°, six peaks that are derived from crystal planes equivalent to the (110) plane are observed. Accordingly, the structural analysis using XRD shows that the directions of a-axes and b-axes are irregularly oriented in the CAAC-OS.

Next, a CAAC-OS analyzed by electron diffraction will be described. For example, when an electron beam with a probe diameter of 300 nm is incident on a CAAC-OS including an InGaZnO₄ crystal in a direction parallel to the formation surface of the CAAC-OS, a diffraction pattern including a spot derived from the (009) plane of the InGaZnO₄ crystal appears. Thus, the electron diffraction also indicates that pellets included in the CAAC-OS have c-axis alignment and that the c-axes are aligned in the direction substantially perpendicular to the formation surface or the top surface of the CAAC-OS. Meanwhile, a ring-like diffraction pattern is shown when an electron beam with a probe diameter of 300 nm is incident on the same sample in a direction perpendicular to the sample surface. It is found that the a-axes and b-axes of the pellets included in the CAAC-OS do not have regular orientation.

In a combined analysis image (also referred to as high-resolution transmission electron microscope (TEM) image) of a bright-field image and a diffraction pattern of the CAAC-OS, which is obtained using a TEM, a plurality of pellets can be observed. However, even in the high-resolution TEM image, a boundary between pellets, that is, a grain boundary is not clearly observed in some cases. Thus, in the CAAC-OS, a reduction in electron mobility due to the grain boundary is less likely to occur.

From the high-resolution TEM image, pellets in which metal atoms are arranged in a layered manner can be observed. The size of a pellet is greater than or equal to 1 nm or greater than or equal to 3 mm Therefore, the pellet can be referred to as a nanocrystal (nc). Furthermore, the CAAC-OS can also be referred to as an oxide semiconductor including c-axis-aligned nanocrystals (CANC). A pellet reflects unevenness of a formation surface or a top surface of the CAAC-OS and is parallel to the formation surface or the top surface of the CAAC-OS.

The pellet is confirmed to have a hexagonal shape. Note that the shape of the pellet is not always a regular hexagon but is a non-regular hexagon in many cases.

A clear grain boundary cannot be observed in the CAAC-OS. In the CAAC-OS, formation of a grain boundary is inhibited by distortion of a lattice arrangement. This is probably because the CAAC-OS can tolerate distortion owing to a low density of arrangement of oxygen atoms in the a-b plane direction, the interatomic bond distance changed by substitution of a metal element, and the like.

As described above, the CAAC-OS has c-axis alignment, its pellets (nanocrystals) are connected in the a-b plane direction, and its crystal structure has distortion. Accordingly, the CAAC-OS can also be referred to as an oxide semiconductor including a c-axis-aligned a-b-plane-anchored (CAA) crystal.

The CAAC-OS is an oxide semiconductor with high crystallinity. Entry of impurities, formation of defects, or the like might decrease the crystallinity of an oxide semiconductor. This means that the CAAC-OS has negligible amounts of impurities and defects (e.g., oxygen vacancies).

Note that impurities mean an element other than the main components of the oxide semiconductor, such as hydrogen, carbon, silicon, and a transition metal element. For example, an element (e.g., silicon) having higher strength of bonding to oxygen than a metal element contained in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

<nc-OS>

Next, an nc-OS will be described.

Analysis of an nc-OS by XRD is described. When the structure of an nc-OS is analyzed by an out-of-plane method, for example, a peak indicating orientation does not appear. That is, a crystal of the nc-OS does not have orientation.

For example, when an electron beam with a probe diameter of 50 nm is incident on a 34-nm-thick region of a thinned nc-OS including an InGaZnO₄ crystal in a direction parallel to the formation surface, a ring-shaped diffraction pattern (nanobeam electron diffraction pattern) is observed. When an electron beam with a probe diameter of 1 nm is incident on the same sample, a plurality of spots are observed in the ring-shaped region. In other words, ordering in an nc-OS is not observed with an electron beam having a probe diameter of 50 nm but is observed with an electron beam having a probe diameter of 1 nm.

When an electron beam with a probe diameter of 1 nm is incident on a region with a thickness less than 10 nm, an electron diffraction pattern in which spots are arranged in an approximately regular hexagonal shape is observed in some cases. This means that an nc-OS in the thickness range of less than 10 nm has a well-ordered region, i.e., a crystal. Note that an electron diffraction pattern having regularity is not observed in some regions because crystals are aligned in various directions.

In a high-resolution TEM image, the nc-OS has a region in which a crystal part is observed, and a region in which a clear crystal part is not observed. In most cases, the size of a crystal part included in the nc-OS is greater than or equal to 1 nm and less than or equal to 10 nm, or specifically, greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS; therefore, a crystal part of the nc-OS may be referred to as a pellet in the following description.

As described above, in the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS or an amorphous oxide semiconductor by some analysis methods.

Since there is no regularity of crystal orientation between the pellets (nanocrystals) as mentioned above, the nc-OS can also be referred to as an oxide semiconductor including random-aligned nanocrystals (RANC) or an oxide semiconductor including non-aligned nanocrystals (NANC).

The nc-OS is an oxide semiconductor that has higher regularity than an amorphous oxide semiconductor; therefore, the nc-OS has a lower density of defect states than an a-like OS and an amorphous oxide semiconductor. Since there is no regularity of crystal orientation between different pellets in the nc-OS, the nc-OS has a higher density of defect states than the CAAC-OS.

<a-Like OS>

An a-like OS has a structure between those of the nc-OS and an amorphous oxide semiconductor.

An a-like OS contains a void and thus has an unstable structure.

For example, growth of a crystal part in the a-like OS is sometimes induced by electron irradiation. In contrast, in the nc-OS and the CAAC-OS, growth of a crystal part is hardly induced by electron irradiation. These results demonstrate that the a-like OS has an unstable structure compared to the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of a single crystal oxide semiconductor having the same composition. The density of each of the nc-OS and the CAAC-OS is higher than or equal to 92.3% and lower than 100% of the density of the single crystal oxide semiconductor having the same composition. It is difficult to deposit an oxide semiconductor having a density lower than 78% of the density of the single crystal oxide semiconductor.

For example, in an oxide semiconductor having an atomic ratio of In:Ga:Zn=1:1:1, the density of single crystal InGaZnO₄ with a rhombohedral crystal structure is 6.357 g/cm³. Accordingly, for the oxide semiconductor having an atomic ratio of In:Ga:Zn=1:1:1, for example, the density of the a-like OS is higher than or equal to 5.0 g/cm³ and lower than 5.9 g/cm³, and the density of each of the nc-OS and the CAAC-OS is higher than or equal to 5.9 g/cm³ and lower than 6.3 g/cm³.

Note that in the case where an oxide semiconductor having a certain composition does not exist in a single crystal structure, single crystal oxide semiconductors with different compositions are combined at an adequate ratio, which makes it possible to calculate a density equivalent to that of a single crystal oxide semiconductor with the desired composition. The density of a single crystal oxide semiconductor with the desired composition can be estimated using a weighted average according to the combination ratio of the single crystal oxide semiconductors with different compositions. Note that it is preferable to use as few kinds of single crystal oxide semiconductors as possible to estimate the density.

As described above, oxide semiconductors have various structures and various properties. Note that an oxide semiconductor may be a stacked layer including two or more films of an amorphous oxide semiconductor, an a-like OS, an nc-OS, and a CAAC-OS, for example.

### Embodiment 7

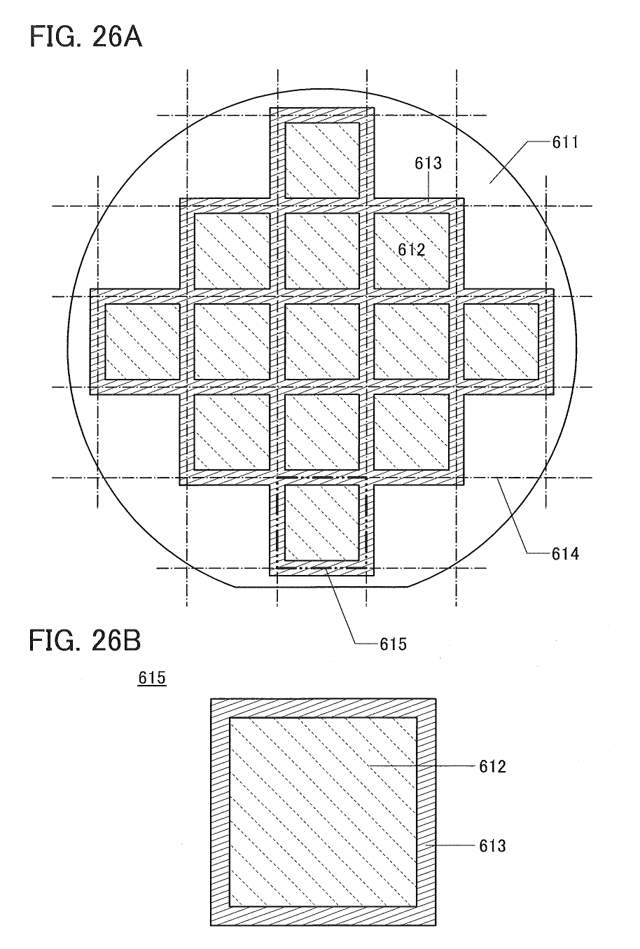

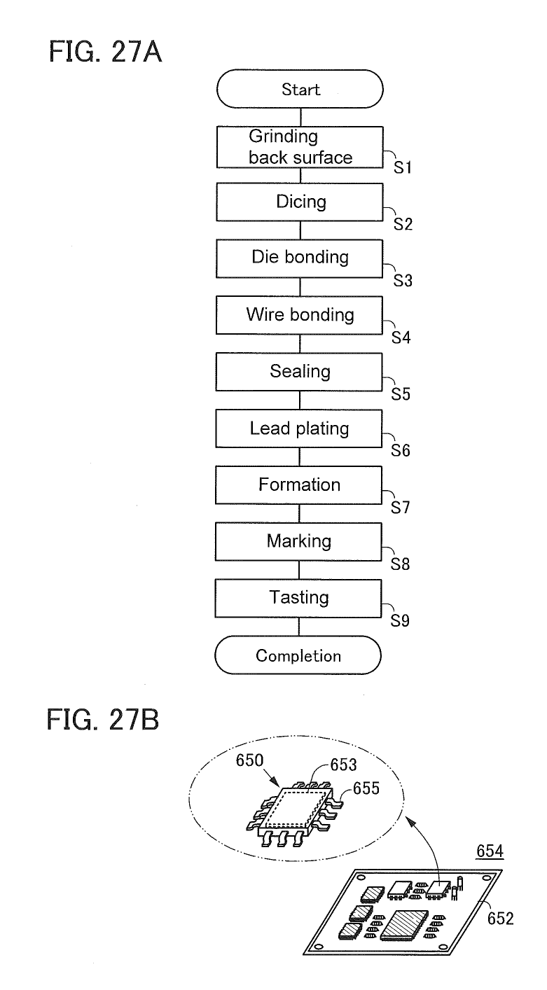

In this embodiment, application examples of the MCU 10 described in Embodiment 1 to an electronic component and to an electronic device including the electronic component will be described with reference to FIGS. 26A and 26B and FIGS. 27A and 27B.

### <Semiconductor Wafer and Chip>

FIG. 26A is a top view illustrating a substrate 611 before dicing treatment. As the substrate 611, a semiconductor substrate (also referred to as semiconductor wafer) can be used, for example. The substrate 611 has a plurality of circuit regions 612. The semiconductor device shown in any of the foregoing embodiments, for example, can be provided in the circuit region 612.

Each of the circuit regions 612 is surrounded by a separation region 613. Separation lines (also referred to as dicing lines) 614 are set at a position overlapping the separation regions 613. Chips 615 each including the circuit region 612 can be cut from the substrate 611 by cutting the substrate 611 along the separation lines 614. FIG. 26B is an enlarged view of the chip 615.

A conductive layer or a semiconductor layer may be provided in the separation regions 613. Providing a conductive layer or a semiconductor layer in the separation regions 613 relieves electrostatic discharge (ESD) that might be caused in a dicing step, preventing a decrease in the yield in the dicing step. A dicing step is generally performed while letting pure water whose specific resistance is decreased by dissolution of a carbonic acid gas or the like flow to a cut portion, in order to cool down a substrate, remove swarf, and prevent electrification, for example. Providing a conductive layer or a semiconductor layer in the separation regions 613 allows a reduction in the usage of the pure water. Therefore, the cost of manufacturing the semiconductor device can be reduced. Moreover, the semiconductor device can be manufactured with improved productivity.

For a semiconductor layer provided in the separation regions 613, it is preferable to use a material having a bandgap greater than or equal to 2.5 eV and less than or equal to 4.2 eV, preferably greater than or equal to 2.7 eV and less than or equal to 3.5 eV. The use of such a material allows accumulated charge to be released slowly; thus, rapid move of charge due to ESD can be suppressed and electrostatic breakdown is less likely to occur.

### <Electronic Component>

FIGS. 27A and 27B show an example where the chip 615 is used to make an electronic component. Note that an electronic component is also referred to as a semiconductor package or an IC package. For electronic components, there are various standards and names corresponding to the direction or the shape of terminals

An electronic component is completed by combining the semiconductor device described in any of the above embodiments and components other than the semiconductor device in the assembly process (post-process).

The post-process is described with reference to a flow chart in FIG. 27A. After an element substrate including the semiconductor device described in any of the above embodiments is completed in the wafer process, a back surface grinding step is performed to grind a back surface (a surface where the semiconductor device and the like are not formed) of the element substrate (Step S1). When the element substrate is thinned by grinding, warpage or the like of the element substrate is reduced, resulting in the reduction in size of the electronic component.

Next, a dicing step is performed to divide the element substrate into a plurality of chips (Step S2). Then, a die bonding step is performed to pick up the divided chips separately and bond them to a lead frame (Step S3). To bond a chip and a lead frame in the die bonding step, resin bonding, tape-automated bonding, or the like is selected as determined as appropriate by products. Note that the chip may be bonded to an interposer instead of the lead frame.

Next, a wire bonding step is performed to electrically connect a lead of the lead frame and an electrode on the chip through a metal fine line (wire) (Step S4). A silver line or a gold line can be used as the metal fine line. Ball bonding or wedge bonding can be used as the wire bonding.

The wire-bonded chip is subjected to a sealing step (molding step) of sealing the chip with an epoxy resin or the like (Step S5). Through the sealing step, the inside of the electronic component is filled with a resin, so that a circuit portion incorporated in the chip and a wire for connecting the chip to the lead can be protected from external mechanical force, and deterioration of characteristics (decrease in reliability) due to moisture or dust can be reduced.

Subsequently, a lead plating step is performed to plate the lead of the lead frame (Step S6). With the plating process, corrosion of the lead can be prevented, and soldering for mounting the electronic component on a printed circuit board in a later step can be performed with higher reliability. Then, a lead processing step is performed to cut and process the lead (Step S7).

Next, a marking step is performed to printing (marking) on a surface of the package (Step S8). After a testing step (Step S9) for checking whether an external shape is good and whether there is malfunction, for example, the electronic component is completed.

FIG. 27B is a schematic perspective view of the completed electronic component. FIG. 27B shows a perspective schematic diagram of a quad flat package (QFP) as an example of the electronic component. An electronic component 650 illustrated in FIG. 27B includes a lead 655 and a semiconductor device 653. As the semiconductor device 653, the semiconductor device described in any of the above embodiments can be used, for instance.

The electronic component 650 in FIG. 27B is, for example, mounted on a printed circuit board 652. A plurality of electronic components 650 are used in combination and electrically connected to each other over the printed wiring board 652; thus, a board 654 on which the electronic components are mounted is completed. The completed board 654 is used in an electronic device or the like.

In this specification and the like, ordinal numbers such as “first,” “second,” and “third” are used in order to avoid confusion among components. Thus, the terms do not limit the number or order of components. For example, in this specification and the like, a “first” component in one embodiment can be referred to as a “second” component in other embodiments or claims. Furthermore, in this specification and the like, a “first” component in one embodiment can be omitted in other embodiments or claims.

In this specification and the like, the term such as “electrode” or “wiring” does not limit a function of a component. For example, an “electrode” is used as part of a “wiring” in some cases, and vice versa. Moreover, the term “electrode” or “wiring” can also mean a plurality of electrodes or wirings formed in an integrated manner.

In this specification and the like, “voltage” and “potential” can be replaced with each other. The term “voltage” refers to a potential difference from a reference potential. Given that the reference potential is a ground potential, for example, “voltage” can be replaced with “potential.” The ground potential does not necessarily mean 0 V. Note that potentials are relative values, and a potential supplied to a wiring or the like is sometimes changed depending on the reference potential.

In this specification and the like, the terms “film” and “layer” can be interchanged with each other depending on the case or circumstances. For example, in some cases, the term “conductive film” can be used instead of “conductive layer,” and the term “insulating layer” can be used instead of “insulating film.”

In this specification and the like, a switch is conducting or not conducting (is turned on or off) to determine whether current flows therethrough or not. Alternatively, a switch has a function of selecting and changing a current path. For example, an electrical switch or a mechanical switch can be used. That is, a switch is not limited to a certain element and can be any element capable of controlling current.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined.

In the case of using a transistor as a switch, the “on state” of the transistor refers to a state in which a source and a drain of the transistor are regarded as being electrically short-circuited. The “off state” of the transistor refers to a state in which the source and the drain of the transistor are regarded as being electrically disconnected. In the case where a transistor operates just as a switch, there is no particular limitation on the polarity (conductivity type) of the transistor.

An example of a mechanical switch is a switch using a microelectroinechanical system (MEMS) technology, such as a digital micromirror device (DMD). Such a switch includes an electrode that can be moved mechanically, and its conduction and non-conduction is controlled with movement of the electrode.

For example, in this specification and the like, an explicit description “X and Y are connected” means that X and Y are electrically connected, X and Y are functionally connected, and X and Y are directly connected. Accordingly, without being limited to a predetermined connection relation (e.g., a connection relation shown in drawings or texts), another connection relation is regarded as being included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows electrical connection between X and Y (e.g., a switch, a transistor, a capacitor, an inductor, a resistor, a diode, a display element, a light-emitting element, or a load) is not connected between X and Y, and the case where X and Y are connected without an element that allows electrical connection between X and Y provided therebetween.

For example, in the case where X and Y are electrically connected, one or more elements that enable electrical connection between X and Y (e.g., a switch, a transistor, a capacitor, an inductor, a resistor, a diode, a display element, a light-emitting element, or a load) can be connected between X and Y. Note that the case where X and Y are electrically connected includes the case where X and Y are directly connected.

For example, in the case where X and Y are functionally connected, one or more circuits that enable functional connection between X and Y (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit capable of increasing signal amplitude, the amount of current, or the like, an operational amplifier, a differential amplifier circuit, a source follower circuit, or a buffer circuit; a signal generator circuit; a memory circuit; and/or a control circuit) can be connected between X and Y. For instance, even if another circuit is provided between X and Y, X and Y are regarded as being functionally connected when a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., X and Y are connected with another element or circuit provided therebetween), X and Y are functionally connected (i.e., X and Y are functionally connected with another element or circuit provided therebetween), and X and Y are directly connected (i.e., X and Y are connected without another element or circuit provided therebetween). That is, in this specification and the like, the term “electrically connected” is substantially the same as the term “connected.”

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include “X, Y, and a source (or a first terminal or the like) and a drain (or a second terminal or the like) of a transistor are electrically connected to each other, and X, the source (or the first terminal or the like) of the transistor, the drain (or the second terminal or the like) of the transistor, and Y are electrically connected in this order,” “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected in this order,” and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order.” When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path,” and “a source (or a first terminal or the like) of a transistor is electrically connected to X through Z1 at least with a first connection path, the first connection path does not include a second connection path, the second connection path includes a connection path through the transistor, a drain (or a second terminal or the like) of the transistor is electrically connected to Y through Z2 at least with a third connection path, and the third connection path does not include the second connection path.” Still another example of the expression is “a source (or a first terminal or the like) of a transistor is electrically connected to X through Z1 on at least a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through Z2 on at least a third electrical path, the third electrical path does not include a fourth electrical path, and the fourth electrical path is an electrical path from the drain (or the second terminal or the like) of the transistor to the source (or the first terminal or the like) of the transistor.” When the connection path in a circuit configuration is defined by an expression similar to the above examples, a source (or a first terminal or the like) and a drain (or a second terminal or the like) of a transistor can be distinguished from each other to specify the technical scope.

Note that the above expressions are examples and there is no limitation on the expressions. Here, X, Y, Z1, and Z2 each denote an object (e.g., a device, an element, a circuit, a wiring, an electrode, a terminal, a conductive film, or a layer).

Even when a circuit diagram shows that independent components are electrically connected to each other, one component has functions of a plurality of components in some cases. For example, when part of a wiring functions as an electrode, one conductive film functions as the wiring and the electrode. Thus, “electrical connection” in this specification also means such a case where one conductive film has functions of a plurality of components.

### Example

In this example, SPICE simulation was executed assuming the memory cell MC12 and the memory cell MC13 to investigate the capacitance and charging time of the capacitors.

SPICE simulation was executed assuming the memory cell MC12 in FIG. 1B and the memory cell MC13 in FIG. 1D. The channel length (L) and channel width (W) of the transistor OS1 were each set to 60 nm. The capacitance (C₁) of the capacitor C1 included in the memory cell MC12 was set to 5 fF. The capacitance (C₂) of the capacitor C2 included in the memory cell MC13 was set to 10 fF, 15 fF, 20 fF, and 25 fF. These values of C₂ correspond to values two times, three times, four times, and five times C₁.

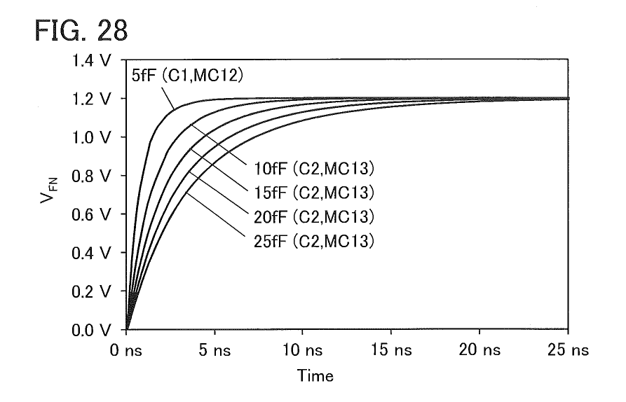

A state where a potential (1.2 V) supplied to the wiring BL is charged to the capacitor through the transistor OS1 was calculated. The calculation results are shown in FIG. 28.

The vertical axis of the graph in FIG. 28 represents a potential (V_{FN}) of the node FN. The horizontal axis of the graph in FIG. 28 represents the lapse time (Time) after a potential of 1.2 V is supplied to the wiring BL and the transistor OS1 is turned on. To turn on the transistor OS1, a potential of 3.3 V was supplied to the wiring WL.

It can be seen from the results in FIG. 28 that the potential of the node FN that is 0 V in an initial state (0 ns) rises over time and filially reaches 1.2 V, and charging is completed. It takes less time for the potential of the capacitor C1 to reach 1.2 V than that of the capacitor C2. That is, data can be written to the memory cell MC12 in a shorter time than to the memory cell MC13. Moreover, it takes more time to write data to the memory cell MC13 with larger C₂.

Table 1 shows the time it takes for V_{FN} to reach 1.08 V, 0.96 V, 0.84 V, 0.72 V, and 0.60 V. Note that the above values of V_{FN} correspond to 90%, 80%, 70%, 60%, and 50% of 1.2 V. That is, Table 1 shows the time to charge the capacitor C2 to 90%, 80%, 70%, 60%, and 50%.

TABLE 1

| | V_{FN} | | | | |
|---|---|---|---|---|---|
| | 1.08 V | 0.96 V | 0.84 V | 0.72 V | 0.60 V |
| C₁, C₂ | (90%) | (80%) | (70%) | (60%) | (50%) |
| 5 fF (C1 in MC12) | 2.0 ns | 1.3 ns | 1.0 ns | 0.7 ns | 0.6 ns |
| 10 fF (C2 in MC13) | 4.0 ns | 2.6 ns | 2.0 ns | 1.4 ns | 1.1 ns |
| 15 fF (C2 in MC13) | 5.9 ns | 3.9 ns | 2.9 ns | 2.1 ns | 1.6 ns |
| 20 fF (C2 in MC13) | 7.9 ns | 5.2 ns | 3.8 ns | 2.8 ns | 2.1 ns |
| 25 fF (C2 in MC13) | 9.9 ns | 6.5 ns | 4.7 ns | 3.5 ns | 2.6 ns |

For example, the assumption is made that data cannot be read from the memory cell MC12 and the memory cell MC13 when V_{FN} is 60% or less (0.72 V or lower).

The memory cell MC12 used in the data memory 12 needs to operate at high speed, and thus preferably has a short charging time. Hence, charging the capacitor C1 to 70%, not to 100%, is considered full charge. When charging is complete, the electric charge held at the node FN decreases over time, and V_{FN} also decreases. In the case of 70% charge, V_{FN} reaches 60% faster than in the case of 100% charge. However, the memory cell MC12 is frequently accessed from the CPU 11, and data is updated before V_{FN} reaches 60%. This means that 70% charge will not cause any problem in the memory cell MC12.

Meanwhile, the memory cell MC13 used in the program memory 13 preferably has a long data retention time. The data retention time is proportional to the amount of electric charge (=capacitance×voltage) stored in the capacitor. When the capacitor C2 has a capacitance of 25 fF and V_{FN} is charged to 90% in the memory cell MC13, the retention time of the memory cell MC13 is 15 times as long as that of the memory cell MC12 charged to 70%, according to the following formula (1).

{25×(1.08−0.72)}/{5×(0.84−0.72)}=15 (1)

The above results confirmed that the operating speed of the memory cell MC12 is higher than that of the memory cell MC13, and that the retention time of the memory cell MC13 can be increased by setting C₂ to two times, three times, four times, or five times C₁.

This application is based on Japanese Patent Application serial no. 2016-015353 filed with Japan Patent Office on Jan. 29, 2016, the entire contents of which are hereby incorporated by reference.

What is claimed is:

1. A semiconductor device comprising:
a CPU;
a first memory cell comprising a first transistor and a first capacitor; and
a second memory cell comprising a second transistor and a second capacitor,
wherein the first memory cell is used as a data memory,
wherein the second memory cell is used as a program memory,
wherein the first transistor comprises an oxide semiconductor in a channel formation region,
wherein the second transistor comprises an oxide semiconductor in a channel formation region,
wherein a capacitance of the second capacitor is larger than a capacitance of the first capacitor, and
wherein data is exchanged between the CPU, the first memory cell, and the second memory cell through a bus.

2. The semiconductor device according to claim 1,
wherein the first capacitor comprises a trench,
wherein the second capacitor comprises a trench, and
wherein the capacitance of the second capacitor is i times the capacitance of the first capacitor, where i is an integer of 2 or more.

3. The semiconductor device according to claim 1, wherein the capacitance of the first capacitor is 5 fF or less.

4. A microcontroller system comprising the semiconductor device according to claim 1.

5. An electronic device comprising:
the semiconductor device according to claim 1; and
a battery.

6. An electronic device comprising:
the semiconductor device according to claim 1;
a sensor;
an antenna; and
a battery.

7. A semiconductor wafer comprising:
a plurality of semiconductor devices according to claim 1; and
a separation region.

8. A semiconductor device comprising:
a CPU;
a first memory cell comprising a first transistor and a first capacitor;
a second memory cell comprising a second transistor and a second capacitor; and
a circuit,
wherein the first memory cell is used as a data memory,
wherein the second memory cell is used as a program memory,
wherein the circuit is used as any one of an analog-to-digital converter, a clock generator, a motor control circuit, and a regenerative control circuit,
wherein the first transistor comprises an oxide semiconductor in a channel formation region,
wherein the second transistor comprises an oxide semiconductor in a channel formation region,
wherein a capacitance of the second capacitor is larger than a capacitance of the first capacitor, and
wherein data is exchanged between the CPU, the first memory cell, the second memory cell, and the circuit through a bus.

9. The semiconductor device according to claim 8,
wherein the first capacitor comprises a trench,
wherein the second capacitor comprises a trench, and
wherein the capacitance of the second capacitor is i times the capacitance of the first capacitor, where i is an integer of 2 or more.

10. The semiconductor device according to claim 8, wherein the capacitance of the first capacitor is 5 ff or less.

11. A microcontroller system comprising the semiconductor device according to claim 8.

12. An electronic device comprising:
the semiconductor device according to claim 8; and
a battery.

13. An electronic device comprising:
the semiconductor device according to claim 8;
a sensor;
an antenna; and
a battery.

14. A semiconductor wafer comprising:
a plurality of semiconductor devices according to claim 8; and
a separation region.
